(19) United States
(12) Patent Application Publication
(10) Pub. No.: US 2011/0033804 A1
(43) Pub. Date: Feb. 10, 2011

(54) PHOTORESIST COMPOSITION

(75) Inventors: Masahiko Shimada, Osaka (JP); Koji Ichikawa, Osaka (JP)

Correspondence Address: BIRCH STEWART KOLASCH & BIRCH, PO BOX 747, FALLS CHURCH, VA, 22040-0747, US

(73) Assignee: SUMITOMO CHEMICAL COMPANY, LIMITED, TOKYO (JP)

(21) Appl. No.: 12/852,072

(22) Filed: Aug. 6, 2010

(30) Foreign Application Priority Data
Aug. 10, 2009 (JP) 2009-185697

(51) Int. Cl. G03F 7/004; C08G 63/00; G03F 7/20

(52) U.S. Cl. 430/285.1; 526/281; 430/322

(57) ABSTRACT

The present invention provides a photoresist composition comprising a resin which comprises a structural unit derived from a compound having an acid-labile group and a structural unit derived from a compound represented by the formula (a):

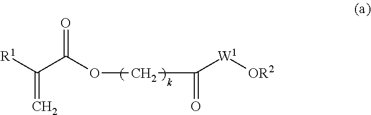

wherein R¹ represents a hydrogen atom, a halogen atom, a C1-C6 alkyl group or a C1-C6 halogenated alkyl group, k represents an integer of 1 to 6, W¹ represents a C6-C18 divalent aromatic hydrocarbon group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group, and R² represents a hydrogen atom, a group represented by the formula (R²-1) or a group represented by the formula (R²-2),

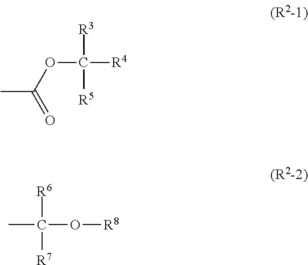

wherein R³, R⁴ and R⁵ independently each represent a C1-C12 hydrocarbon group, and R³ and R⁴ can be bonded each other to form a ring, R⁶ and R⁷ independently each represent a hydrogen atom or a C1-C12 hydrocarbon group, and R⁸ represents a C1-C12 hydrocarbon group, and
which is insoluble or poorly soluble in an alkali aqueous solution but becomes soluble in an alkali aqueous solution by the action of an acid.

This nonprovisional application claims priority under 35 U.S.C. §119(a) on Patent Application No. 2009-185697 filed in JAPAN on Aug. 10, 2009, the entire contents of which are hereby incorporated by reference.

### FIELD OF THE INVENTION

The present invention relates to a photoresist composition.

### BACKGROUND OF THE INVENTION

A photoresist composition used for semiconductor microfabrication employing a lithography process contains an acid generator comprising a compound generating an acid by irradiation.

US 2003/0099900 A1 discloses a photoresist composition comprising a resin which comprises a structural unit derived from 2-ethyl-2-adamantyl methacrylate and a structural unit derived from p-hydroxystyrene.

### SUMMARY OF THE INVENTION

The present invention is to provide a photoresist composition.

The present invention relates to the followings:

<1> A photoresist composition comprising a resin which comprises a structural unit derived from a compound having an acid-labile group and a structural unit derived from a compound represented by the formula (a):

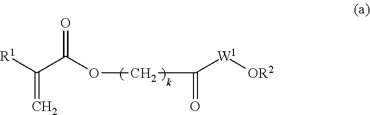

wherein R¹ represents a hydrogen atom, a halogen atom, a C1-C6 alkyl group or a C1-C6 halogenated alkyl group, k represents an integer of 1 to 6, W¹ represents a C6-C18 divalent aromatic hydrocarbon group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group, and R² represents a hydrogen atom, a group represented by the formula (R²-1) or a group represented by the formula (R²-2),

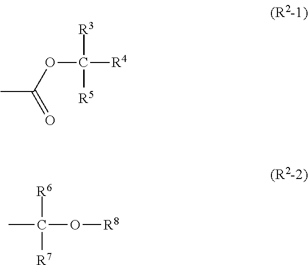

wherein R³, R⁴ and R⁵ independently each represent a C1-C12 hydrocarbon group, and R³ and R⁴ can be bonded each other to form a ring, R⁶ and R⁷ independently each represent a hydrogen atom or a C1-C12 hydrocarbon group, and R⁸ represents a C1-C12 hydrocarbon group, and
which is insoluble or poorly soluble in an alkali aqueous solution but becomes soluble in an alkali aqueous solution by the action of an acid;
<2> The photoresist composition according to <1>, wherein W¹ is a phenylene group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group;
<3> The photoresist composition according to <1> or <2>, wherein k is 1;
<4> The photoresist composition according to any one of <1> to <3>, wherein the compound represented by the formula (a) is a compound represented by the formula (a-1) or (a-2):

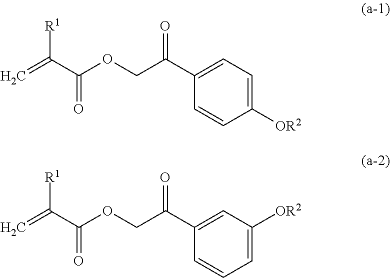

wherein R¹ and R² are the same as defined in <1>;
<5> The photoresist composition according to any one of <1> to <4>, wherein the photoresist composition further contains an acid generator;
<6> The photoresist composition according to any one of <1> to <5>, wherein the photoresist composition further contains a basic compound;
<7> A process for producing a photoresist pattern comprising the following steps (1) to (5):
(1) a step of applying the photoresist composition according to any one of <1> to <6> on a substrate,
(2) a step of forming a photoresist film by conducting drying,
(3) a step of exposing the photoresist film to radiation,
(4) a step of baking the exposed photoresist film, and
(5) a step of developing the baked photoresist film with an alkaline developer, thereby forming a photoresist pattern.

### DESCRIPTION OF PREFERRED EMBODIMENTS

The present photoresist composition comprises a resin which comprises a structural unit derived from a compound having an acid-labile group and a structural unit derived from a compound represented by the formula (a):

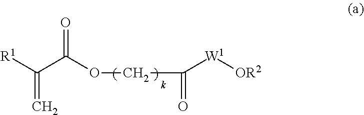

wherein R¹ represents a hydrogen atom, a halogen atom, a C1-C6 alkyl group or a C1-C6 halogenated alkyl group, k represents an integer of 1 to 6, W¹ represents a C6-C18 divalent aromatic hydrocarbon group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group, and R² represents a hydrogen atom, a group represented by the formula (R²-1) or a group represented by the formula (R²-2),

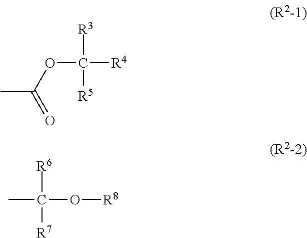

wherein R³, R⁴ and R⁵ independently each represent a C1-C12 hydrocarbon group, and R³ and R⁴ can be bonded each other to form a ring, R⁶ and R⁷ independently each represent a hydrogen atom or a C1-C12 hydrocarbon group, and R⁸ represents a C1-C12 hydrocarbon group (hereinafterm simply referred to as the compound (a)) and which is insoluble or poorly soluble in an alkali aqueous solution but becomes soluble in an alkali aqueous solution by the action of an acid.

Examples of the halogen atom represented by R¹ include a fluorine atom, a chlorine atom, a bromine atom and an iodine atom.

Examples of the C1-C6 alkyl group represented by R¹ include a methyl group, an ethyl group, a propyl group, an isopropyl group, a butyl group and a tert-butyl group, and a methyl group is preferable.

Examples of the C1-C6 halogenated alkyl group represented by R¹ include a trifluoromethyl group, a pentafluoroethyl group, a heptafluoropropyl group and a nonafluorobutyl group, and a trifluoromethyl group is preferable.

R¹ is preferably a hydrogen atom or a C1-C6 alkyl group, and is more preferably a hydrogen atom or a methyl group.

In the formula (a), k is preferably 1 or 2, and more preferably 1.

Examples of C6-C18 divalent aromatic hydrocarbon group represented by W¹ include a phenylene group, a naphthylene group, an anthrylene group and a biphenylene group, and a phenylene group is preferable. The C6-C18 divalent aromatic hydrocarbon group can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group. Examples of the halogen atom include a fluorine atom, a chlorine atom, a bromine atom and an iodine atom. Examples of the C1-C12 alkyl group include a methyl group, an ethyl group, a propyl group, an isopropyl group, a butyl group, an isobutyl group, a sec-butyl group, a tert-butyl group, a pentyl group, a hexyl group, a heptyl group, an octyl group, a 2-ethylhexyl group, a nonyl group, a decyl group, an undecyl group and a dodecyl group. Examples of the C1-C12 alkoxy group include a methoxy group, an ethoxy group, a propoxy group, an isopropoxy group, a butoxy group, an isobutoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group. Examples of the C6-C14 aryl group include a phenyl group, a naphthyl group, an anthryl group, a p-methylphenyl group, a p-tert-butylphenyl group and a p-adamantylphenyl group. Examples of the C7-C15 aralkyl group include a benzyl group, a phenylethyl group, a phenylpropyl group, a trityl group, a naphthylmethyl group and a naphthylethyl group. Examples of the C2-C4 acyl group include an acetyl group, a propionyl group and a butyryl group.

Examples of the C6-C18 divalent aromatic hydrocarbon group having one or more substituents include a 5-methyl-1,3-phenylene group, a 5-tert-butyl-1,3-phenylene group, a 5-adamantyl-1,3-phenylene group, a 2-methyl-1,4-phenylene group, a 2,6-dimethyl-1,4-phenylene group, a 2-methyl-1,4-naphthylene group and a 2-methyl-9,10-anthrylene group.

Examples of the C1-C12 hydrocarbon group represented by R³, R⁴, R⁵, R⁶, R⁷ and R⁸ in the formulae (R²-1) and (R²-2) include a C1-C12 alkyl group, a C3-C12 alicyclic hydrocarbon group, a C6-C12 aryl group, a C7-C12 aralkyl group and a group formed by combining two or more above-mentioned groups. The C6-C12 aryl group and the C7-C12 aralkyl group can have one or more substituents selected from the group consisting of a C1-C6 alkyl group, a C1-C6 alkoxy group and a halogen atom. Examples of the C1-C12 alkyl group include a methyl group, an ethyl group, a propyl group, an isopropyl group, a butyl group, an isobutyl group, a sec-butyl group, a tert-butyl group, a pentyl group, a 1-methylbutyl group, a 2-methylbutyl group, a 3-methylbutyl group, a 1-ethylpropyl group, a 2-ethylpropyl group, a hexyl group, a 1-methylpentyl group, a 2-methylpentyl group, a 3-methylpentyl group, a 4-methylpentyl group, a 1-ethylbutyl group, a 2-ethylbutyl group, a 3-ethylbutyl group, a heptyl group, an octyl group, a 2-ethylhexyl group, a tert-octyl group, a nonyl group, a decyl group, an undecyl group and a dodecyl group. Examples of the C3-C12 alicyclic hydrocarbon group include a cyclopropyl group, a cyclobutyl group, a cyclopentyl group, a cyclohexyl group, a cycloheptyl group, a cyclooctyl group, a cyclononyl group, a cyclodecyl group, a 1-adamantyl group, a 2-adamantyl group and an isobornyl group. Examples of the C6-C12 aryl group include a phenyl group, a tolyl group, a methoxyphenyl group and a naphthyl group. Examples of the C7-C12 aralkyl group include a benzyl group, a chloromethoxyphenylethyl group and a methoxybenzyl group. Examples of the group formed by combining two or more above-mentioned groups include the followings.

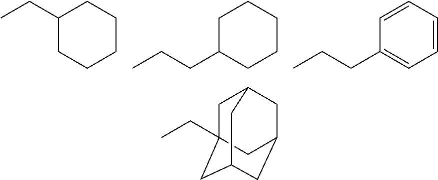

Examples of the C1-C6 alkyl group as the substituent of the C6-C12 aryl and C7-C12 aralkyl groups include a methyl group, an ethyl group, a propyl group, an isopropyl group, a butyl group, a tert-butyl group, a pentyl group and a hexyl group, and examples of the C1-C6 alkoxy group as the substituent of the C6-C12 aryl and C7-C12 aralkyl groups include a methoxy group, an ethoxy group, a propoxy group, an isopropoxy group, a butoxy group, a tert-butoxy group, a pentyloxy group and a hexyloxy group, and examples of the halogen atom as the substituent of the C6-C12 aryl and C7-C12 aralkyl groups include a fluorine atom, a chlorine atom, a bromine atom and an iodine atom.

Examples of the ring formed by bonding R³ and R⁴ each other include a cyclopropane ring, a cyclobutane ring, a cyclopentane ring, a cyclohexane ring, a cycloheptane ring, a cyclooctane ring, a cyclononane ring, a cyclodecane ring and an adamantane ring.

It is preferred that R³, R⁴ and R⁵ independently each represent a C1-C12 alkyl group, a C3-C12 alicyclic hydrocarbon group, a C6-C12 aryl group or a C7-C12 aralkyl group, or R³ and R⁴ are bonded each other to form a cyclohexane ring or an adamantane ring. It is more preferred that R³, R⁴ and R⁵ independently each represent a C1-C6 alkyl group or a C3-C12 alicyclic hydrocarbon group, or R³ and R⁴ are bonded each other to form a cyclohexane ring or an adamantane ring. It is especially preferred that R³, R⁴ and R⁵ independently each represent a methyl group or an ethyl group, or R³ and R⁴ are bonded each other to form a cyclohexane ring or an adamantane ring.

Examples of the group represented by the formula (R²-1) include the followings.

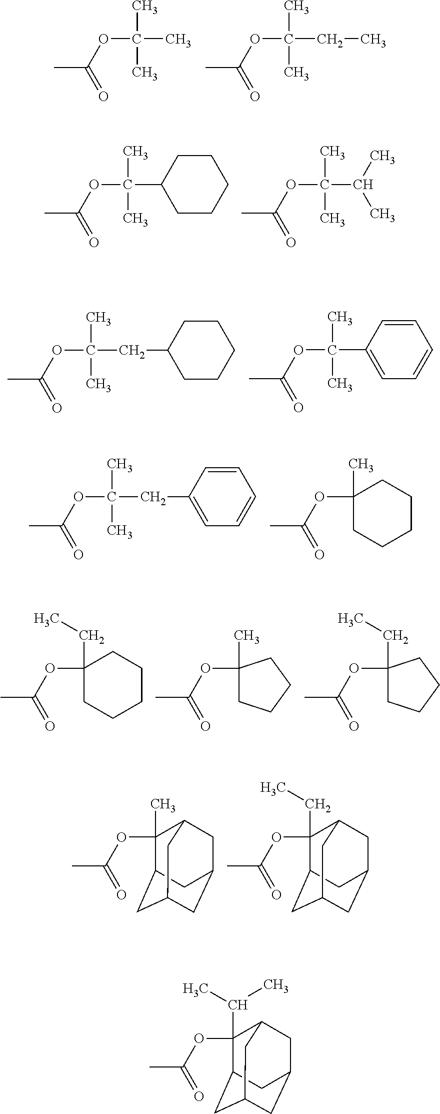

It is preferred that R⁶ and R⁷ independently each represent a hydrogen atom, a C1-C12 alkyl group or a C3-C12 alicyclic hydrocarbon group. It is more preferred that R⁶ and R⁷ independently each represent a hydrogen atom or a C1-C6 alkyl group. It is especially preferred that R⁶ and R⁷ independently each represent a hydrogen atom, a methyl group or an ethyl group. R⁸ is preferably a C1-C12 alkyl group, a C3-C12 alicyclic hydrocarbon group, C6-C12 aryl group or a group formed by combining two or more above-mentioned groups, more preferably a C1-C8 alkyl group, a C3-C12 alicyclic hydrocarbon group or a group formed by combining the C1-C8 alkyl group and the C3-C12 alicyclic hydrocarbon group, and especially preferably a methyl group, an ethyl group, a cyclohexyl group, a cyclohexylmethyl group or a cyclohexylethyl group.

Examples of the group represented by the formula (R²-2) include the followings.

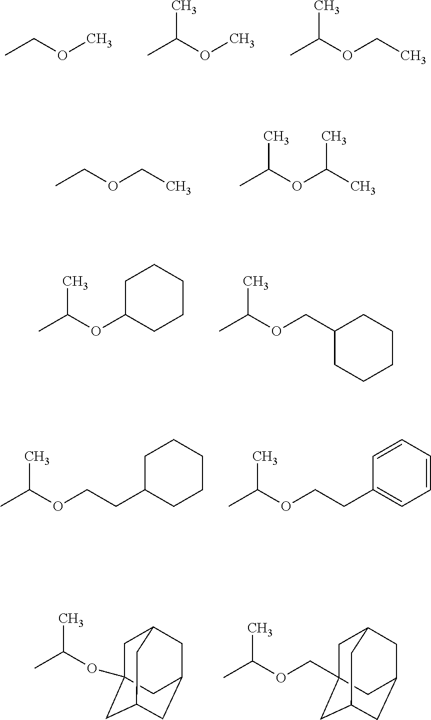

R² is preferably a hydrogen atom.

A compound represented by the formula (a-1) or (a-2) is preferable as the compound (a).

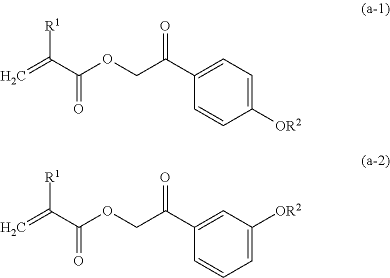

wherein R¹ and R² are the same as described above.

Preferable examples of the compound (a) include the following compounds represented by the formulae (a-3) to (a-16).

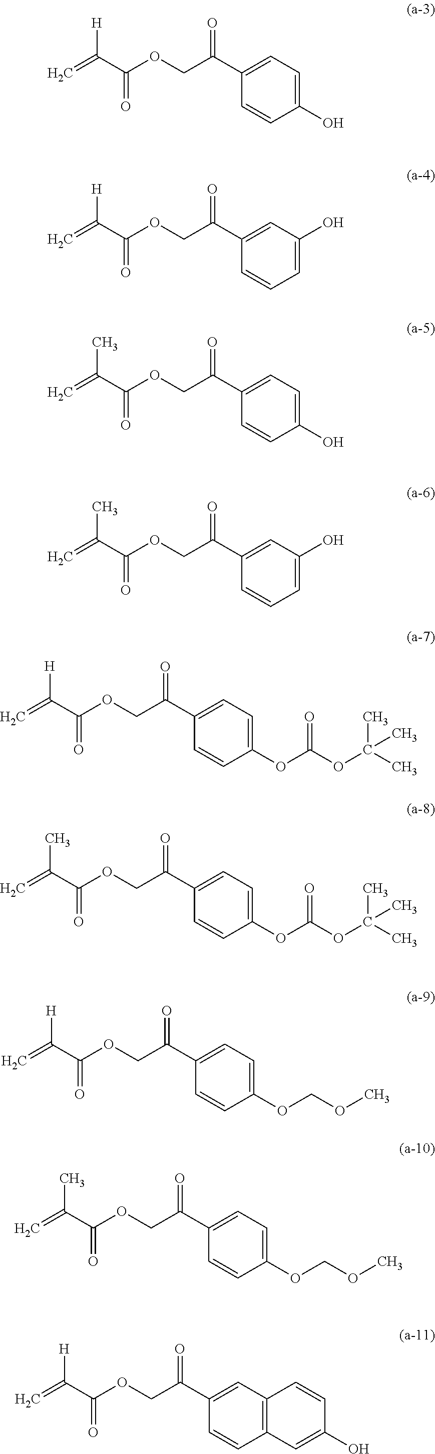

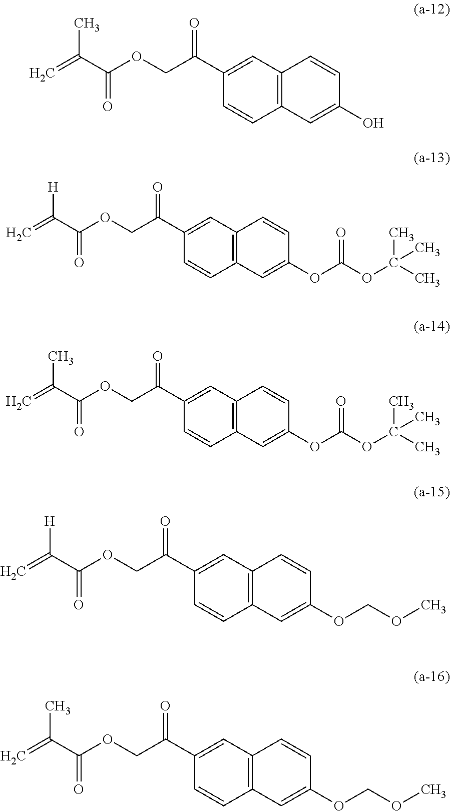

The compound (a) can be produced by reacting a compound represented by the formula (a-b) with a compound represented by the formula (a-c) in a solvent such as N,N-dimethylformamide in the presence of a catalyst such as a mixture of potassium carbonate and potassium iodide. Examples of the compound represented by the formula (a-c) include acrylic acid and methacrylic acid. The compound represented by the formula (a-b) can be produced by replacing a hydrogen atom of the terminal methyl group of the compound represented by the formula (a-a) by a halogen atom in a solvent such as chloroform.

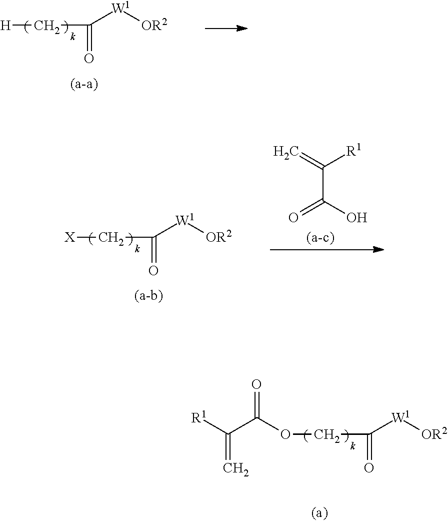

wherein W¹, R¹, R² and k are the same as described above.

The resin can contain two or more kinds of structural units derived from the compound (a).

The content of the structural unit derived from the compound (a) in the resin is usually 5 to 95 mol % and preferably 10 to 90 mol % based on total molar of all the structural units of the resin. The content of the structural unit derived from the compound having an acid-labile group is usually 95 to 5 mol % and preferably 90 to 10 mol % based on total molar of all the structural units of the resin.

The resin comprises a structural unit derived from the compound having an acid-labile group.

In this specification, “an acid-labile group” means a group capable of being eliminated by the action of an acid.

Examples of the acid-labile group include a group represented by the formula (10):

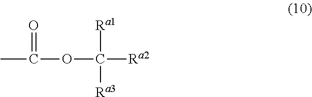

wherein R^{a1}, R^{a2} and R^{a3} independently each represent a C1-C8 aliphatic hydrocarbon group or a C3-C20 alicyclic hydrocarbon group, or R^{a1} and R^{a2} are bonded each other to form a C3-C20 ring.

Examples of the C1-C8 aliphatic hydrocarbon group include a C1-C8 alkyl group such as a methyl group, an ethyl group, a propyl group, an isopropyl group, a butyl group, a pentyl group, a hexyl group, a heptyl group and an octyl group. The C3-C20 alicyclic hydrocarbon group may be monocyclic or polycyclic, and examples thereof include a monocyclic alicyclic hydrocarbon group such as a C3-C20 cycloalkyl group (e.g. a cyclopentyl group, a cyclohexyl group, a methylcyclohexyl group, a dimethylcyclohexyl group, a cycloheptyl group and a cyclooctyl group) and a polycyclic alicyclic hydrocarbon group such as a decahydronaphthyl group, an adamantyl group, a norbornyl group, a methylnorbornyl group, and the followings:

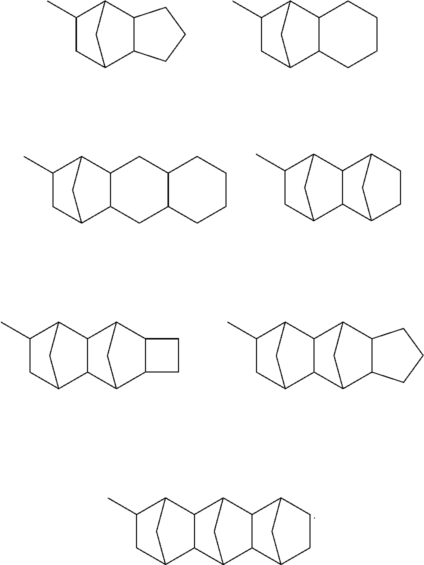

The alicyclic hydrocarbon group preferably has 3 to 16 carbon atoms.

Examples of the ring formed by bonding R^{a1} and R^{a2} each other include the following groups and the ring preferably has 3 to 12 carbon atoms.

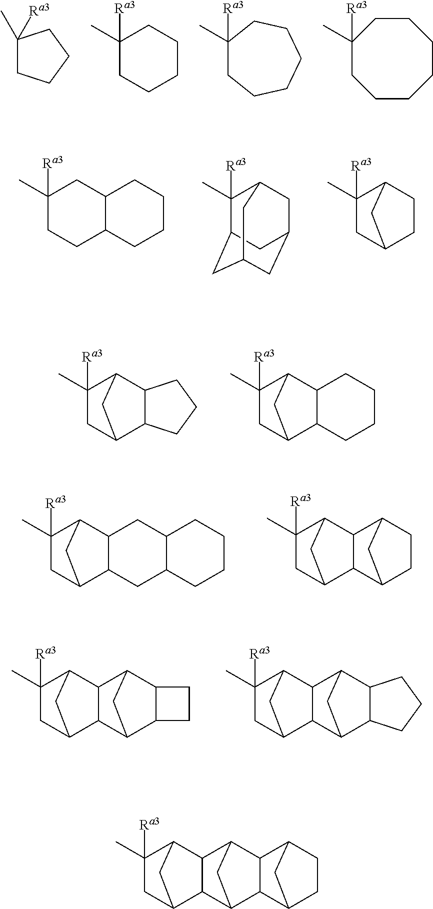

wherein R^{a3} is the same as defined above.

The group represented by the formula (10) wherein R^{a1}, R^{a2} and R^{a3} independently each represent a C1-C8 alkyl group such as a tert-butyl group, the group represented by the formula (10) wherein R^{a1} and R^{a2} are bonded each other to form an adamantyl ring and R^{a3} is a C1-C8 alkyl group such as a 2-alkyl-2-adamantyl group, and the group represented by the formula (10) wherein R^{a1} and R^{a2} are C1-C8 alkyl groups and R^{a3} is an adamantyl group such as a 1-(1-adamantyl)-1-alkylalkoxycarbonyl group are preferable.

An acrylate monomer having an acid-labile group in its side chain or a methacryalte monomer having an acid-labile group in its side chain is preferable.

Preferable examples of the compound having an acid-labile group include a 2-alkyl-2-adamantyl acrylate, a2-alkyl-2-adamantyl methacrylate, 1-(1-adamantyl)-1-alkylalkyl acrylate, a 1-(1-adamantyl)-1-alkylalkyl methacrylate, a 2-alkyl-2-adamantyl 5-norbornene-2-carboxylate, a 1-(1-adamantyl)-1-alkylalkyl 5-norbornene-2-carboxylate, a 2-alkyl-2-adamantyl α-chloroacrylate and a 1-(1-adamantyl)-1-alkylalkyl α-chloroacrylate. Particularly when the 2-alkyl-2-adamantyl acrylate or the 2-alkyl-2-adamantyl methacrylate is used, a photoresist composition having excellent resolution tends to be obtained. Typical examples thereof include 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate, 2-butyl-2-adamantyl acrylate, 2-methyl-2-adamantyl α-chloroacrylate and 2-ethyl-2-adamantyl α-chloroacrylate. When particularly 2-ethyl-2-adamantyl acrylate, 2-ethyl-2-adamantyl methacrylate, 2-isopropyl-2-adamantyl acrylate or 2-isopropyl-2-adamantyl methacrylate is used, a photoresist composition having excellent sensitivity and heat resistance tends to be obtained.

The 2-alkyl-2-adamantyl acrylate can be usually produced by reacting a 2-alkyl-2-adamantanol or a metal salt thereof with an acrylic halide, and the 2-alkyl-2-adamantyl methacrylate can be usually produced by reacting a 2-alkyl-2-adamantanol or a metal salt thereof with a methacrylic halide.

The resin can have two or more kinds of structural units derived from the compounds having an acid-labile group.

The resin preferably contains one or more structural units having one or more highly polar substituents. Examples of the structural unit having one or more highly polar substituents include a structural unit having a hydrocarbon group having at least one selected from the group consisting of a hydroxyl group, a cyano group, a nitro group and an amino group and a structural unit having a hydrocarbon group having one or more —CO—O—, —CO—, —O—, —SO₂— or —S—. A structural unit having a saturated cyclic hydrocarbon group having a cyano group or a hydroxyl group, a structural unit having a saturated cyclic hydrocarbon group in which one or more —CH₂— replaced by —O— or —CO—, and a structural unit having a lactone structure in its side chain are preferable, and a structural unit having a bridged hydrocarbon group having one or more hydroxyl groups, and a structural unit having a bridged hydrocarbon group having —CO—O— or —CO— are more preferable. Examples thereof include a structural unit derived from 2-norbornene having one or more hydroxyl groups, a structural unit derived from acrylonitrile or methacrylonitrile, a structural unit derived from hydroxyl-containing adamantyl acrylate or hydroxyl-containing adamantyl methacrylate, a structural unit derived from styrene monomer such as p-hydroxystyrene and m-hydroxystyrene, a structural unit derived from a structural unit derived from 1-adamantyl acrylate or 1-adamantyl methacrylate, and a structural unit derived from acryloyloxy-γ-butyrolactone or methacryloyloxy-γ-butyrolactone having a lactone ring which may have an alkyl group.

Specific examples of the structural unit derived from hydroxyl-containing adamantyl acrylate or hydroxyl-containing adamantyl methacrylate include a structural unit derived from 3-hydroxy-1-adamantyl acrylate; a structural unit derived from 3-hydroxy-1-adamantyl methacrylate; a structural unit derived from 3,5-dihydroxy-1-adamantyl acrylate; and a structural unit derived from 3,5-dihydroxy-1-adamantyl methacrylate.

3-Hydroxy-1-adamantyl acrylate, 3-hydroxy-1-adamantyl methacrylate, 3,5-dihydroxy-1-adamantyl acrylate and 3,5-dihydroxy-1-adamantyl methacrylate can be produced, for example, by reacting corresponding hydroxyadamantane with acrylic acid, methacrylic acid or its acid halide, and they are also commercially available.

When the resin has a structural unit derived from hydroxyl-containing adamantyl acrylate or hydroxyl-containing adamantyl methacrylate, the content thereof is preferably 5 to 50% by mole based on 100% by mole of all the structural units of the resin.

Examples of the structural unit derived from a monomer having a lactone ring which may have an alkyl group include a structural unit derived from acryloyloxy-γ-butyrolactone, a structural unit derived from methacryloyloxy-γ-butyrolactone and structural units represented by the formulae (a′) and (b′):

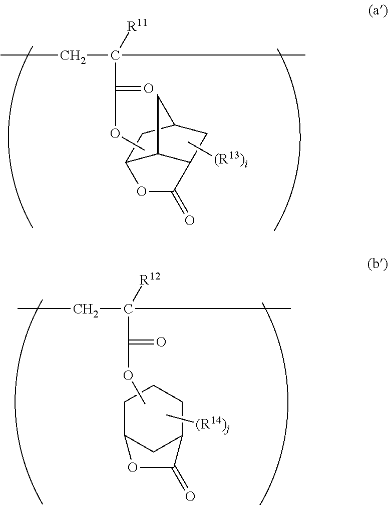

wherein R¹¹ and R¹² independently each represents a hydrogen atom or a methyl group, R¹³ and R¹⁴ are independently in each occurrence a hydrogen atom, a methyl group, a trifluoromethyl group or a halogen atom, and i and j independently each represents an integer of 1 to 3.

Further, the acryloyloxy-γ-butyrolactone and the methacryloyloxy-γ-butyrolactone can be produced by reacting corresponding α- or β-bromo-γ-butyrolactone with acrylic acid or methacrylic acid, or reacting corresponding α- or β-hydroxy-γ-butyrolactone with the acrylic halide or the methacrylic halide.

Examples of the monomers giving structural units represented by the formulae (a′) and (b′) include an acrylate of alicyclic lactones and a methacrylate of alicyclic lactones having the hydroxyl group described below, and mixtures thereof. These esters can be produced, for example, by reacting the corresponding alicyclic lactone having the hydroxyl group with acrylic acid or methacrylic acid, and the production method thereof is described in, for example, JP 2000-26446 A.

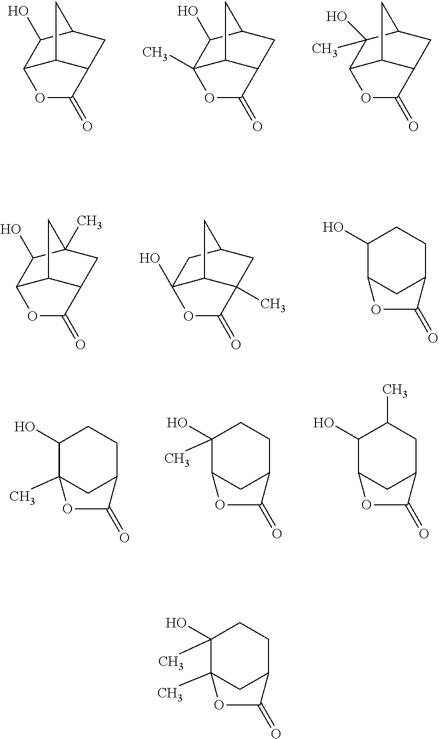

Examples of the acryloyloxy-γ-butyrolactone and the methacryloyloxy-γ-butyrolactone in which lactone ring may be substituted with the alkyl group include α-acryloyloxy-γ-butyrolactone, α-methacryloyloxy-γ-butyrolactone, α-acryloyloxy-β,β-dimethyl-γ-butyrolactone, α-methacryloyloxy-β,β-dimethyl-γ-butyrolactone, α-acryloyloxy-α-methyl-γ-butyrolactone, α-methacryloyloxy-α-methyl-γ-butyrolactone, β-acryloyloxy-γ-butyrolactone, β-methacryloyloxy-γ-butyrolactone and β-methacryloyloxy-α-methyl-γ-butyrolactone.

When the resin has a structural unit derived from a monomer having a lactone ring which may have an alkyl group, the content thereof is preferably 5 to 50% by mole based on 100% by mole of all the structural units of the resin.

Among them, the structural unit derived from 3-hydroxy-1-adamantyl acrylate, the structural unit derived from 3-hydroxy-1-adamantyl methacrylate, the structural unit derived from 3,5-dihydroxy-1-adamantyl acrylate, the structural unit derived from 3,5-dihydroxy-1-adamantyl methacrylate, the structural unit derived from α-acryloyloxy-γ-butyrolactone, the structural unit derived from α-methacryloyloxy-γ-butyrolactone, the structural unit derived from β-acryloyloxy-γ-butyrolactone, the structural unit derived from β-methacryloyloxy-γ-butyrolactone, the structural unit represented by the formula (a′) and the structural unit represented by the formula (b′) are preferable, because a photoresist composition having good resolution and adhesiveness of photoresist to a substrate tends to be obtained.

When the exposing is conducted using KrF excimer laser, the resin preferably has a structural unit derived from a styrene monomer such as p-hydroxystyrene and m-hydroxystyrene, and the content thereof is preferably 5 to 90% by mole based on 100% by mole of all the structural units of the resin.

The resin can contain the other structural unit or units. Examples thereof include a structural unit derived from acrylic acid or methacrylic acid, a structural unit derived from an alicyclic compound having an olefinic double bond such as a structural unit represented by the formula (c′):

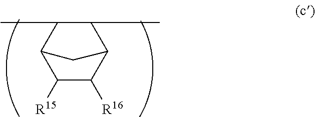

wherein R¹⁵ and R¹⁶ each independently represents a hydrogen atom, a C1-C3 alkyl group, a carboxyl group, a cyano group or a —COOU group in which U represents an alcohol residue, or R¹⁵ and R¹⁶ can be bonded together to form a carboxylic anhydride residue represented by —C(═O)OC(═O)—,
a structural unit derived from an aliphatic unsaturated dicarboxylic anhydride such as a structural unit represented by the formula (d′):

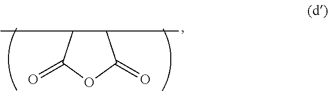

or
a structural unit represented by the formula (e′):

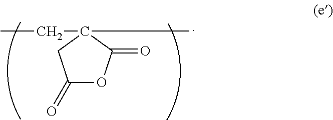

In R¹⁵ and R¹⁶, examples of the C1-C3 alkyl group include a methyl group, an ethyl group, a propyl group and an isopropyl group. The —COOU group is an ester formed from the carboxyl group, and examples of the alcohol residue corresponding to U include an optionally substituted C1-C8 alkyl group, 2-oxooxolan-3-yl group and 2-oxooxolan-4-yl group, and examples of the substituent on the C1-C8 alkyl group include a hydroxyl group and an alicyclic hydrocarbon group.

Specific examples of the monomer giving the structural unit represented by the above-mentioned formula (c′) may include 2-norbornene, 2-hydroxy-5-norbornene, 5-norbornene-2-carboxylic acid, methyl 5-norbornene-2-carboxylate, 2-hydroxyethyl 5-norbornene-2-carboxylate, 5-norbornene-2-methanol and 5-norbornene-2,3-dicarboxylic anhydride.

When U in the —COOU group is the acid-labile group, the structural unit represented by the formula (c′) is a structural unit having the acid-labile group even if it has the norbornane structure. Examples of monomers giving a structural unit having the acid-labile group include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxylcyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

When the resin has a structural unit derived from the compound having no acid-labile group, the content of the structural unit derived from the compound having no acid-labile group is usually 3 to 50 mol % and preferably 5 to 30 mol % based on total molar of all the structural units of the resin.

The resin usually has 2,500 or more of the weight-average molecular weight and 100,000 or less of the weight-average molecular weight, preferably has 2,700 or more of the weight-average molecular weight and 50,000 or less of the weight-average molecular weight, and more preferably 3,000 or more of the weight-average molecular weight and 40,000 or less of the weight-average molecular weight. The weight-average molecular weight can be measured with gel permeation chromatography.

The content of the resin in the photoresist composition is usually 80 to 99.9% by weight based on sum of solid component, and the content of the acid generator is usually 0.1 to 20% by weight based on sum of solid component. Herein, “solid component” means the components other than a solvent among all components of the photoresist composition.

The resin can be obtained by conducting polymerization reaction of the compound (a) and the compound having an acid-labile group. The polymerization reaction is usually carried out in the presence of a radical initiator. This polymerization reaction can be conducted according to known methods.

The present photoresist composition preferably contains an acid generator.

The acid generator is a substance which is decomposed to generate an acid by applying a radiation such as a light, an electron beam or the like on the substance itself or on a photoresist composition containing the substance. The acid generated from the acid generator acts on the resin resulting in cleavage of the acid-labile group existing in the resin.

Examples of the acid generator include a nonionic acid generator, an ionic acid generator and the combination thereof. Examples of the nonionic acid generator include an organo-halogen compound, a sulfone compound such as a disulfone, a ketosulfone and a sulfonyldiazomethane, a sulfonate compound such as a 2-nitrobenzylsulfonate, an aromatic sulfonate, an oxime sulfonate, an N-sulfonyloxyimide, a sulfonyloxyketone and DNQ 4-sulfonate. Examples of the ionic acid generator include an onium salt compound such as a diazonium salt, a phosphonium salt, a sulfonium salt and an iodonium salt. Examples of the anion of the onium salt include a sulfonic acid anion, a sulfonylimide anion and a sulfonulmethide anion. The onium salt compound is preferable.

Other examples of the acid generator include acid generators described in JP 63-26653 A, JP 55-164824 A, JP 62-69263 A, JP 63-146038 A, JP 63-163452 A, JP 62-153853 A, JP 63-146029 A, U.S. Pat. No. 3,779,778, U.S. Pat. No. 3,849,137, DE Patent No. 3914407 and EP Patent No. 126,712.

Preferable examples of the acid generator include diphenyliodonium trifluoromethanesulfonate, (4-methoxyphenyl)(phenyl)iodonium hexafluoroantimonate, (4-methoxyphenyl)(phenyl)iodonium trifluoromethanesulfonate, bis(4-tert-butylphenyl)iodonium tetrafluorobarate, bis(4-tert-butylphenyl)iodonium hexafluorophosphate, bis(4-tert-butylphenyl)iodonium hexafluoroantimonate, bis(4-tert-butylphenyl)iodonium trifluoromethanesulfonate, triphenylsulfonium 2,4,6-triisopropylbenzenesulfonate, triphenylsulfonium hexafluorophosphate, triphenylsulfonium hexafluoroantimonate, triphenylsulfonium trifluoromethanesulfonate, (4-methylphenyl)diphenylsulfonium perfluorobutanesulfonate, (4-methylphenyl)diphenylsulfonium perfluorooctanesulfonate, (4-methoxyphenyl)diphenylsulfonium hexafluoroantimonate, (4-methoxyphenyl)diphenylsulfonium trifluoromethanesulfonate, (p-tolyl)diphenylsulfonium trifluoromethanesulfonate, (2,4,6-trimethylphenyl)diphenylsulfonium trifluoromethanesulfonate, (4-tert-butylphenyl)diphenylsulfonium trifluoromethanesulfonate, (4-phenylthiophenyl)diphenylsulfonium hexafluorophosphate, (4-phenylthiophenyl)diphenylsulfonium hexafluoroantimonate, 1-(2-naphthoylmethyl)thiolanium hexafluoroantimonate, 1-(2-naphthoylmethyl)thiolanium trifluoromethanesulfonate, (4-hydroxyl-1-naphthyl)dimethylsulfonium hexafluoroantimonate, (4-hydroxyl-1-naphthyl)dimethylsulfonium trifluoromethanesulfonate, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolan-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, 2-(4-pentyloxystyryl)-4,6-bis(trichloromethyl)-1,3,5-triazine, 1-benzoyl-1-phenylmethyl p-toluenesulfonate, 2-benzoyl-2-hydroxy-2-phenylethyl p-toluenesulfonate, 1,2,3-benzenetriyl tris(methanesulfonate), 2,6-dinitrobenzyl p-toluenesulfonate, 2-nitrobenzyl p-toluenesulfonate, 4-nitrobenzyl p-toluenesulfonate, diphenyl disulfone, di-p-tolyl disulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cylohexylsulfonyl)diazomethane, (benzoyl)(phenylsulfonyl)diazomethane, N-(phenylsulfonyloxy)succinimide, N-(trifluoromethylsulfonyloxy)succinimide, N-(trifluoromethylsulfonyloxy)phthalimide, N-(trifluoromethylsulfonyloxy)-5-norbornene-2,3-dicarboxyimide, N-(trifluoromethylsulfonyloxy)naphthalimide, N-(10-camphorsulfonyloxy)naphthalimide, and a salt represented by the formula (I):

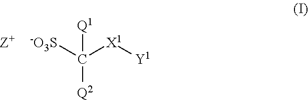

wherein Q¹ and Q² each independently represent a fluorine atom or a C1-C6 perfluoroalkyl group,
X¹ represents a single bond or a C1-C17 saturated divalent hydrocarbon group which can have one or more substituents, and one or more methylene groups in the saturated divalent hydrocarbon group can be replaced by —O— or —CO—,
Y¹ represents a C1-C36 aliphatic hydrocarbon group, a C3-C36 alicyclic hydrocarbon group or a C6-C36 aromatic hydrocarbon group, and the aliphatic hydrocarbon group, the alicyclic hydrocarbon group and the aromatic hydrocarbon group can have one or more substituents, and one or more methylene groups in the aliphatic hydrocarbon group and the alicyclic hydrocarbon group can be replaced by —O— or —CO—, Z⁺ represents an organic cation.

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Q¹ and Q² each independently preferably represent a fluorine atom or a trifluoromethyl group, and Q¹ and Q² are more preferably fluorine atoms.

Examples of the C1-C17 saturated divalent hydrocarbon group include a C1-C17 alkylene group and a divalent group having an alicyclic divalent hydrocarbon group. Examples of the alkylene group include a methylene group, an ethylene group, a trimethylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an isopropylene group, a sec-bytylene group and a tert-butylene group. Examples of the divalent group having an alicyclic divalent hydrocarbon group include the following groups represented by the formulae (X¹-A) to (X¹-C):

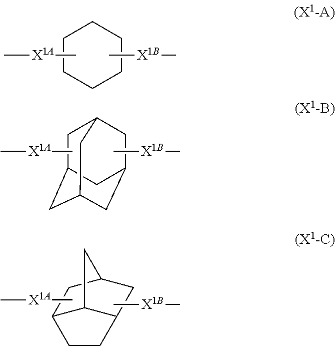

wherein X^{1A} and X^{1B} independently each represent a C1-C6 alkylene group which can have one or more substituents, with the proviso that total carbon number of the group represented by the formula (X¹-A), (X¹-B) or (X¹-C) is 1 to 17.

One or more methylene groups in the C1-C6 alkylene group can be replaced by —O— or —CO—.

Examples of the saturated hydrocarbon group in which one or more methylene groups are replaced by —O— or —CO— include —CO—O—X¹⁰—, —CO—O—X¹¹—CO—O—, —X¹²—O—CO— and —X¹³—O—X¹⁴—, wherein X¹⁰ and X¹² independently each represent a single bond or a C1-C15 saturated hydrocarbon group, X¹¹ represents a single bond or a C1-C13 saturated hydrocarbon group, X¹³ represents a single bond or a C1-C16 saturated hydrocarbon group, and X¹⁴ represents a single bond or a C1-C16 saturated hydrocarbon group, with proviso that total carbon number of X¹³ and X¹⁴ is 1 to 16. Preferred is —CO—O—(CH₂)ₕ— wherein h is an integer of 0 to 10.

Examples of the substituent in Y¹ include a halogen atom, a hydroxyl group, a cyano group, an oxo group, a glycidyloxy group, a C2-C4 acyl group, a C1-C6 alkoxy group, a C2-C7 alkoxycarbonyl group, a C1-C12 aliphatic hydrocarbon group, a C3-C20 alicyclic hydrocarbon group, a C6-C20 aromatic hydrocarbon group and a C7-C21 aralkyl group.

The salt represented by the formula (I) is preferable as the acid generator.

Examples of the anion part of the salt represented by the formula (I) include anion parts represented by the formulae (IA), (IB), (IC) and (ID), and the anion parts represented by the formulae (IA) and (IB) are preferable.

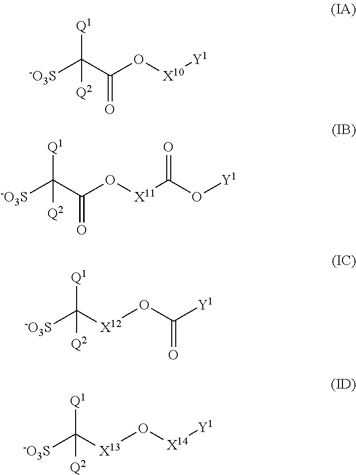

wherein Q¹, Q², X¹⁰, X¹¹, X¹², X¹³, X¹⁴ and Y¹ are the same as defined above.

Y¹ is preferably a C3-C36 alicyclic hydrocarbon group which can have one or more substituents and in which one or more methylene groups can be replaced by —O— or —CO—. Examples thereof include groups represented by the formulae (W1) to (W25):

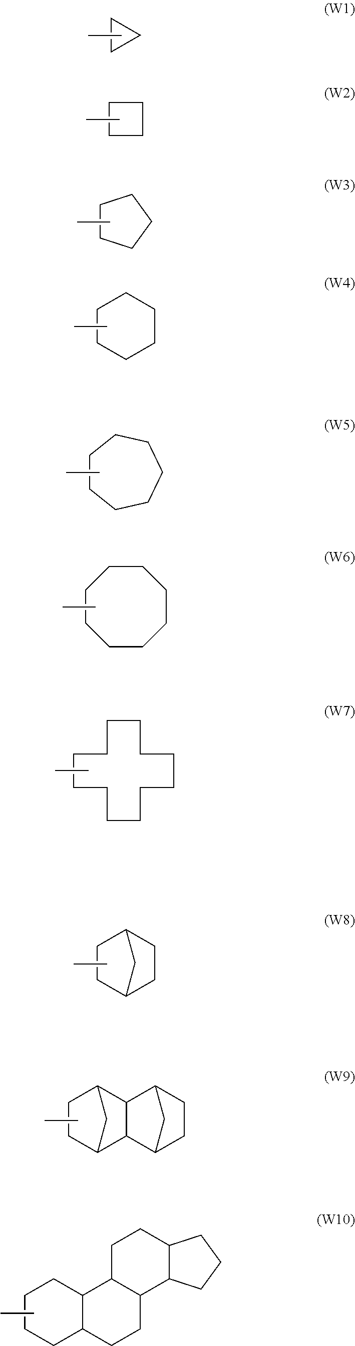

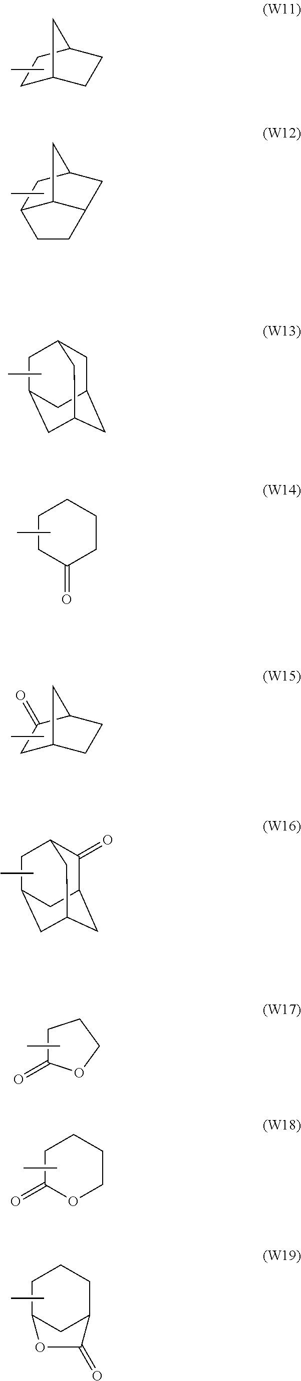

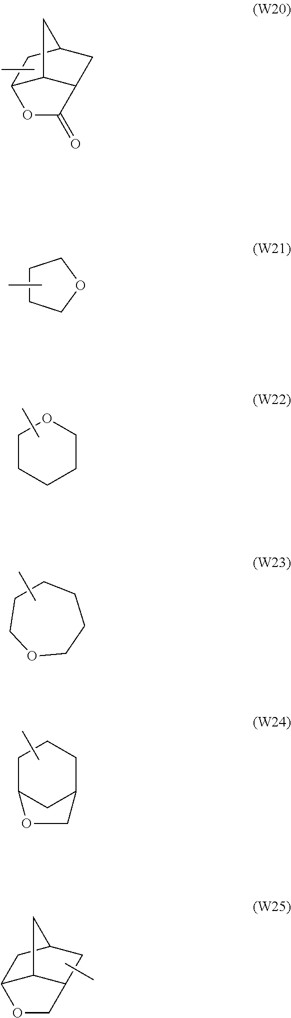

The above-mentioned groups represented by the formulae (W1) to (W25) can have one or more substituents. Among them, a group represented by the formula (Y1), (Y2), (Y3) and (Y4):

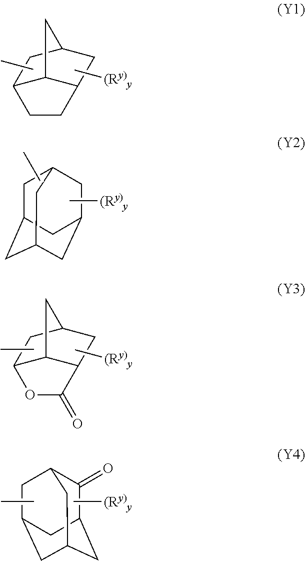

wherein R^{y} represents a halogen atom, a hydroxyl group, a C1-C12 alkyl group, a C1-C12 alkoxy group, a C6-C12 aryl group, a C7-C12 aralkyl group, a glycidyloxy group or a C2-C4 acyl group, and y represents an integer of 0 to 6, is preferable.

Examples of Y¹ include the followings:

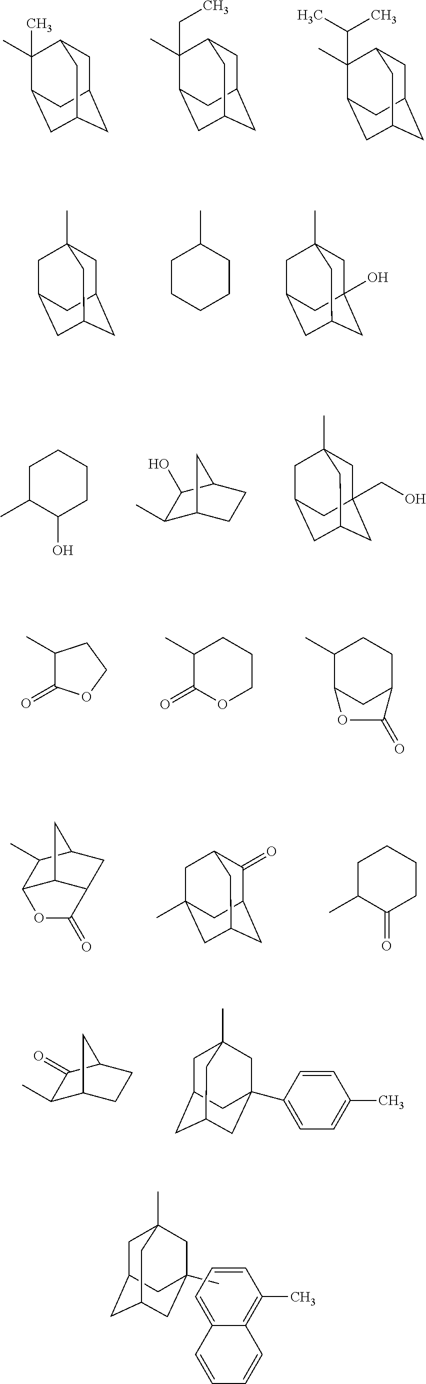

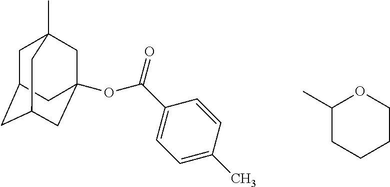

Examples of the anion part represented by the formula (IA) include the followings.

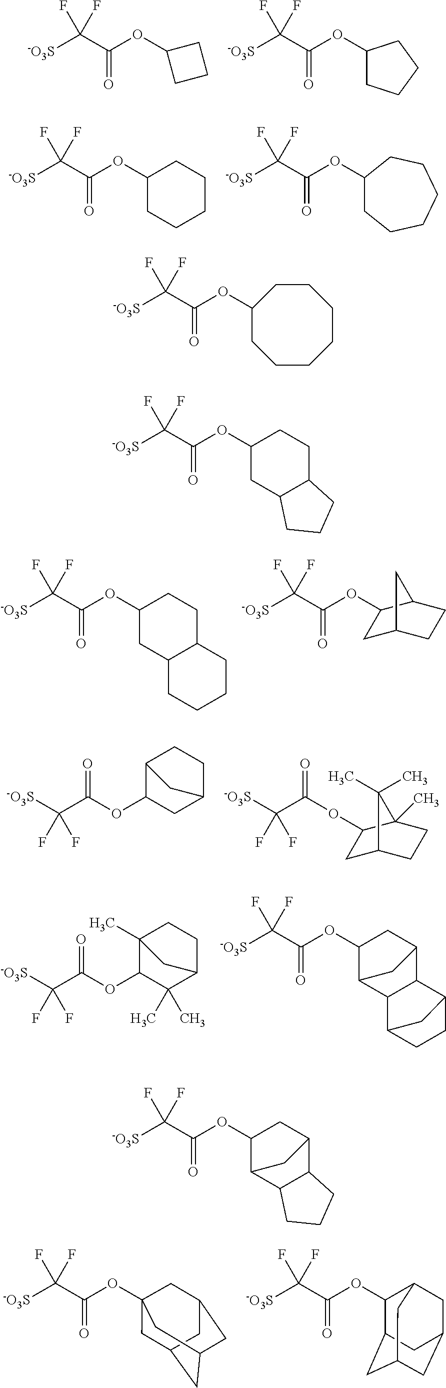

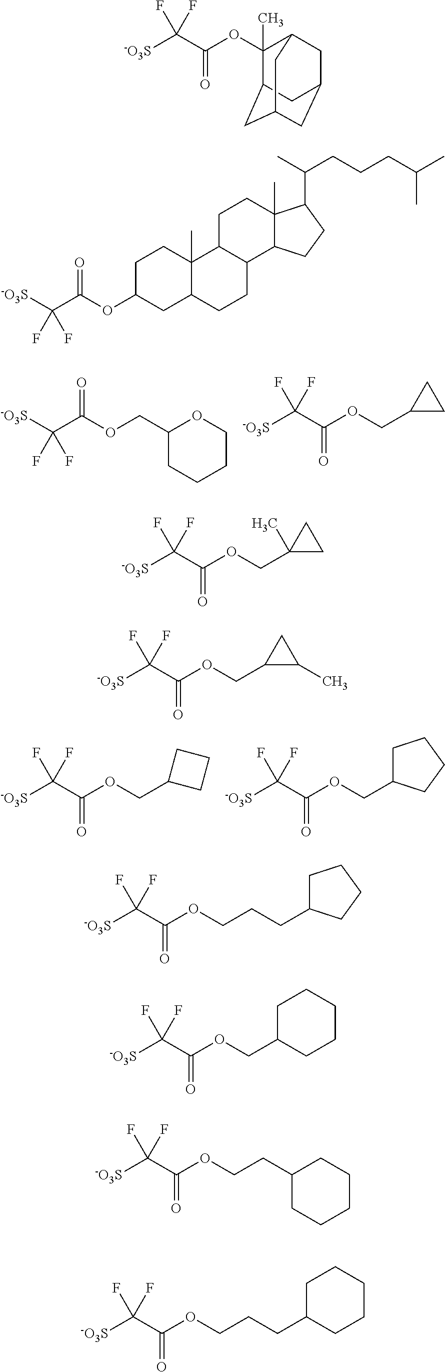

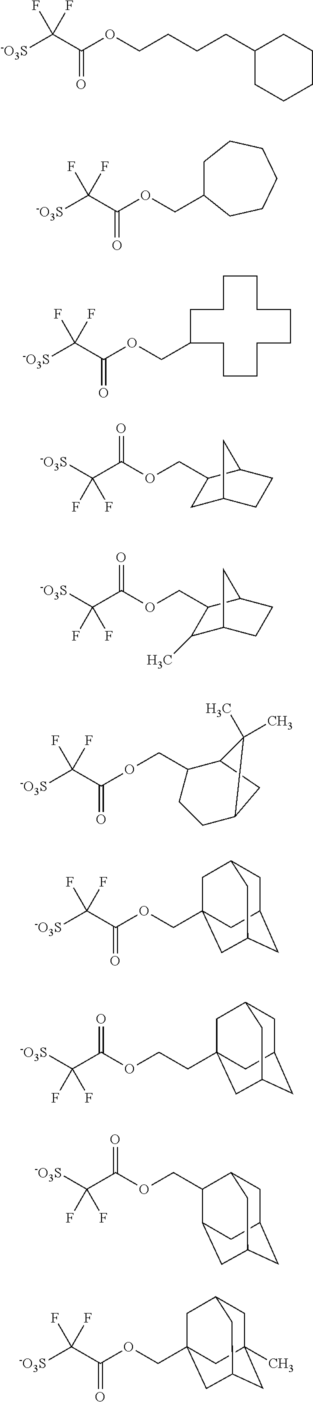

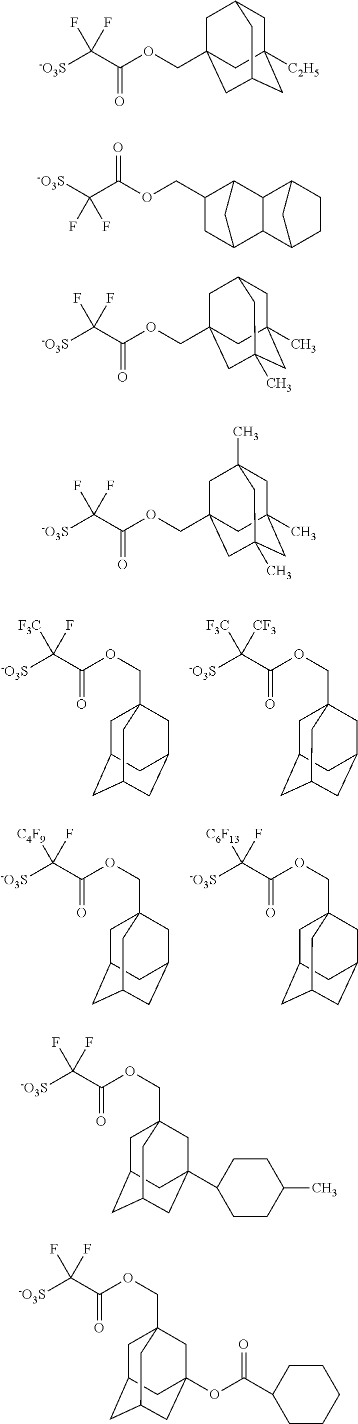

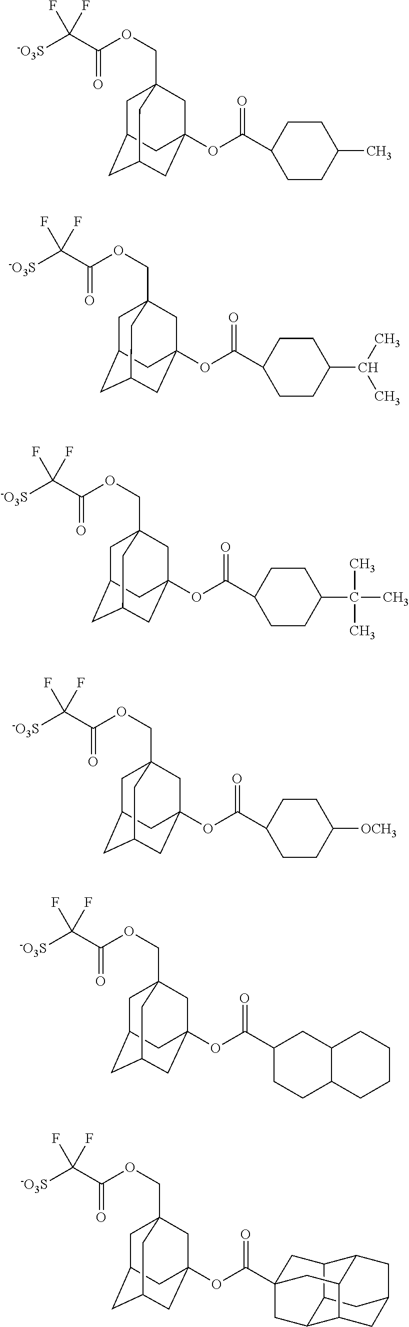

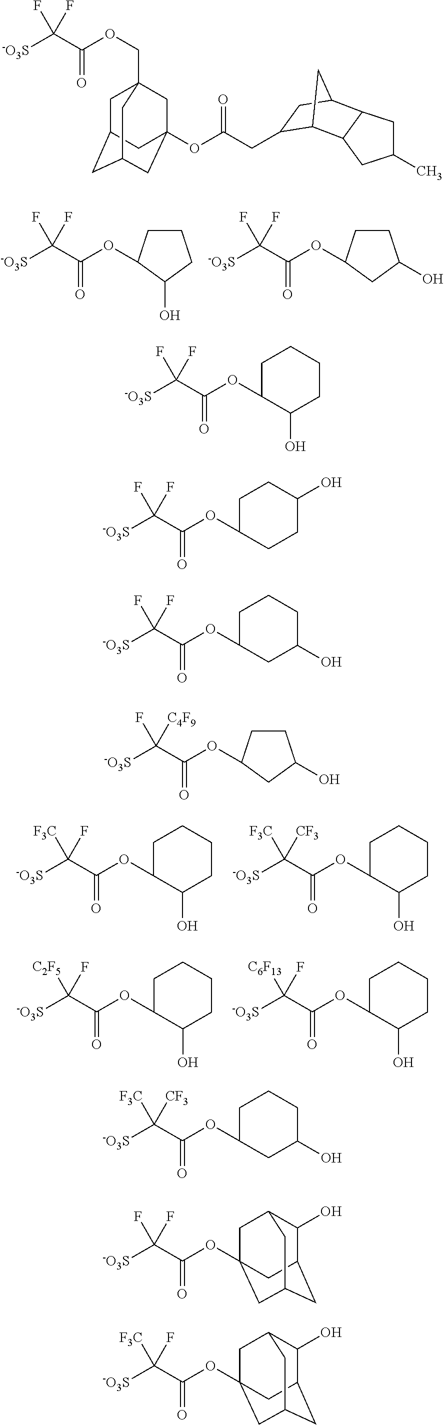

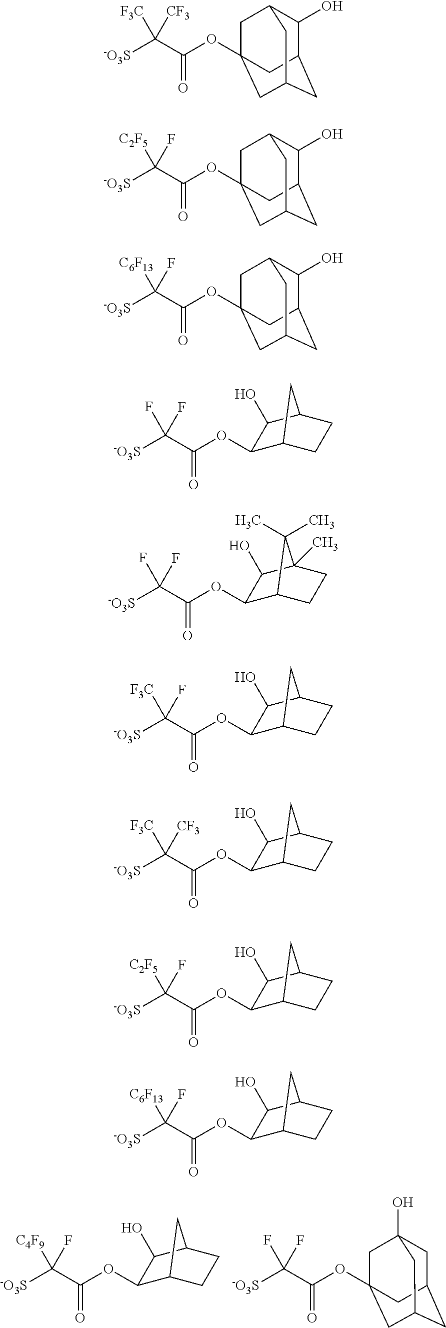

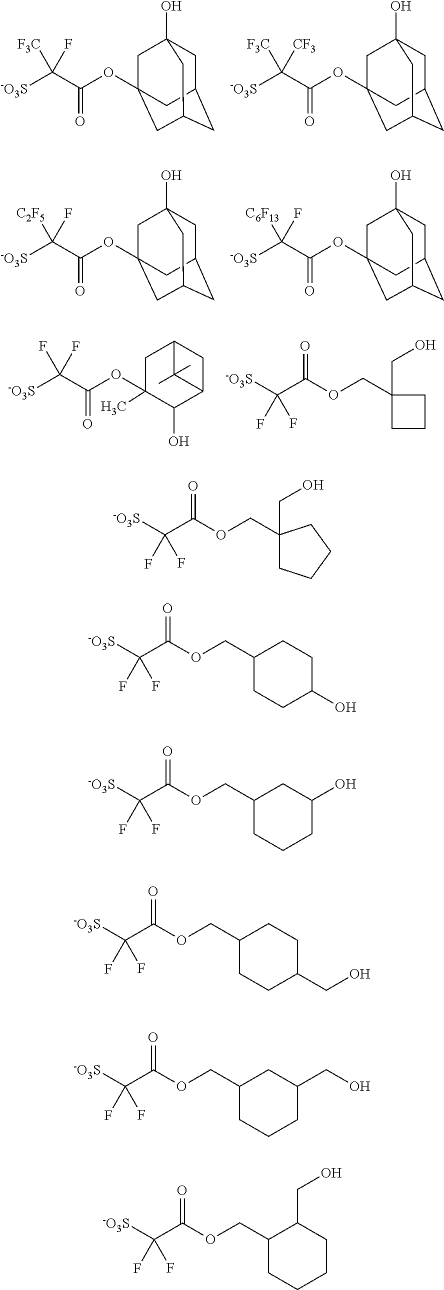

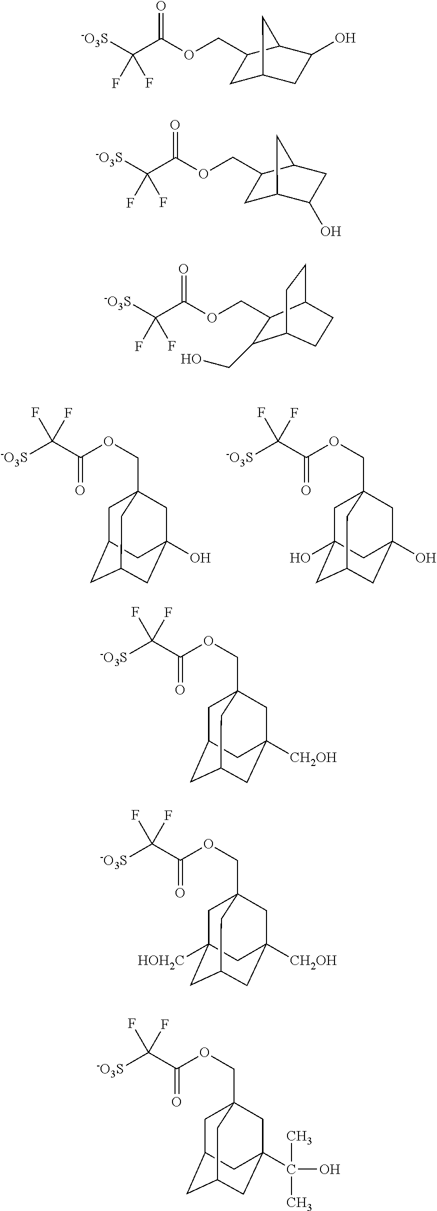

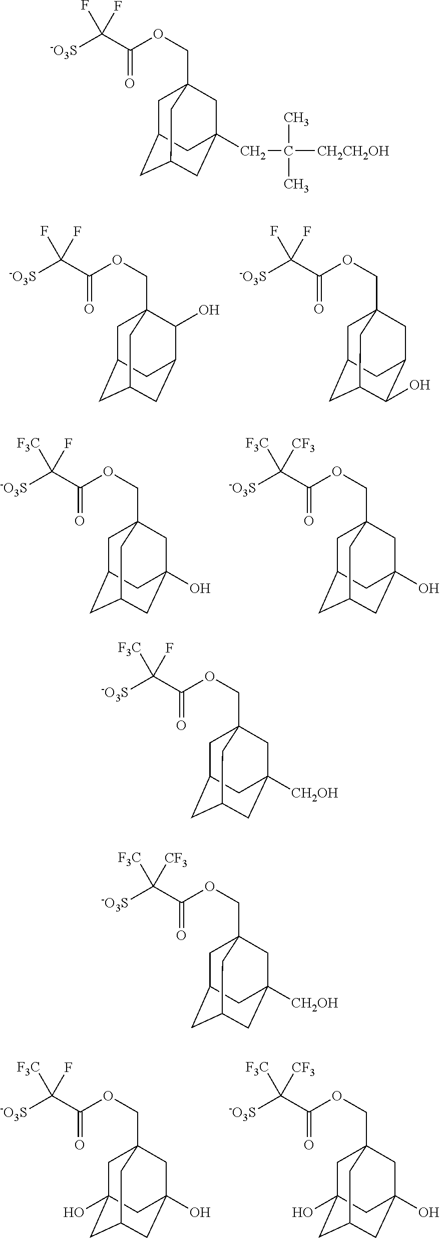

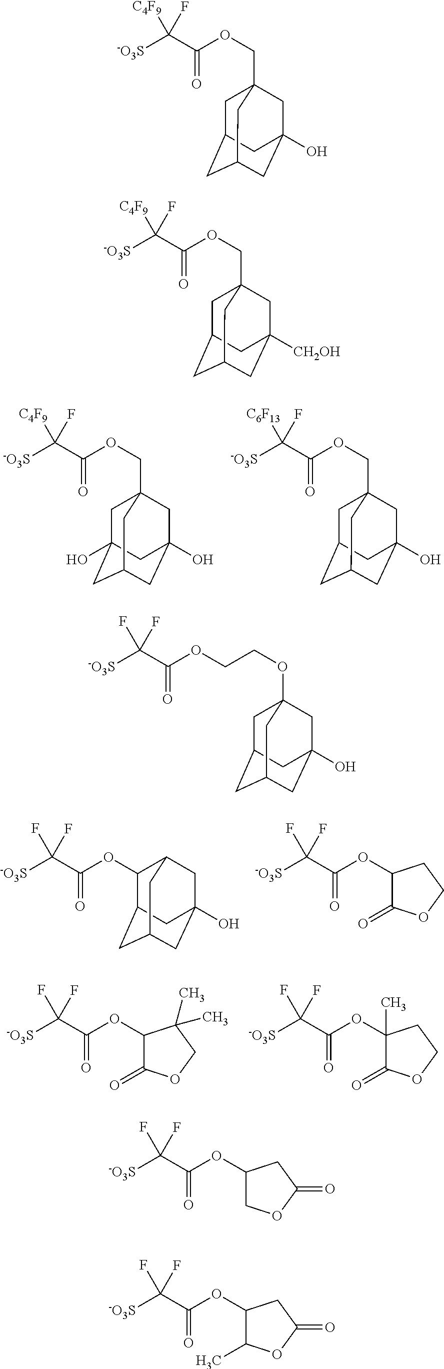

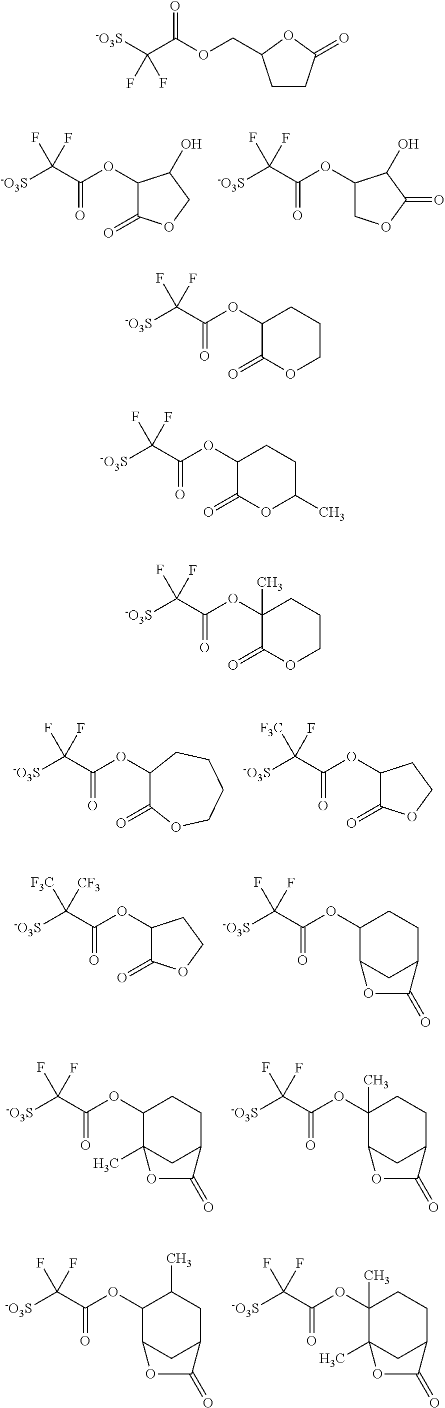

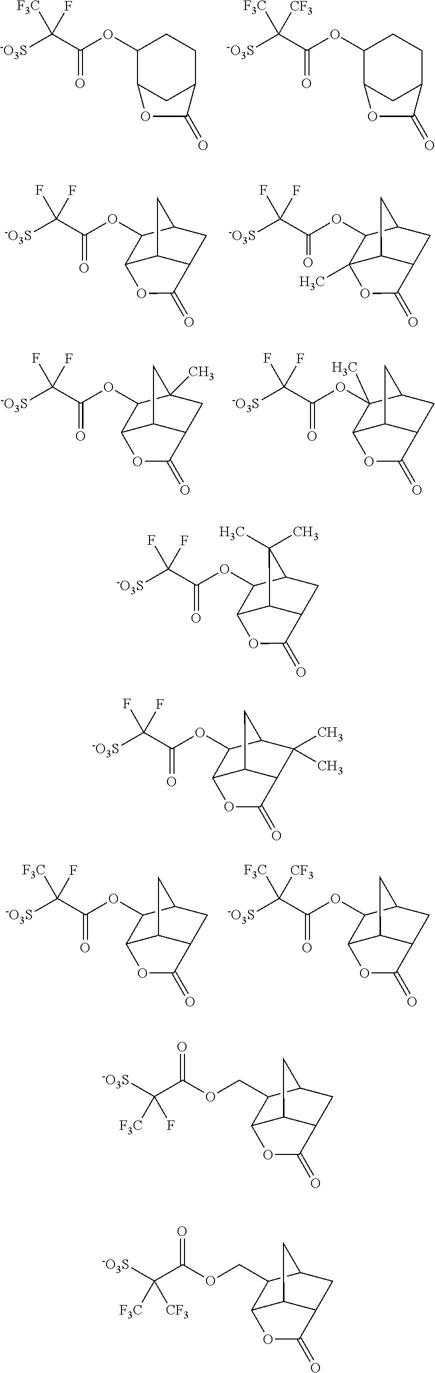

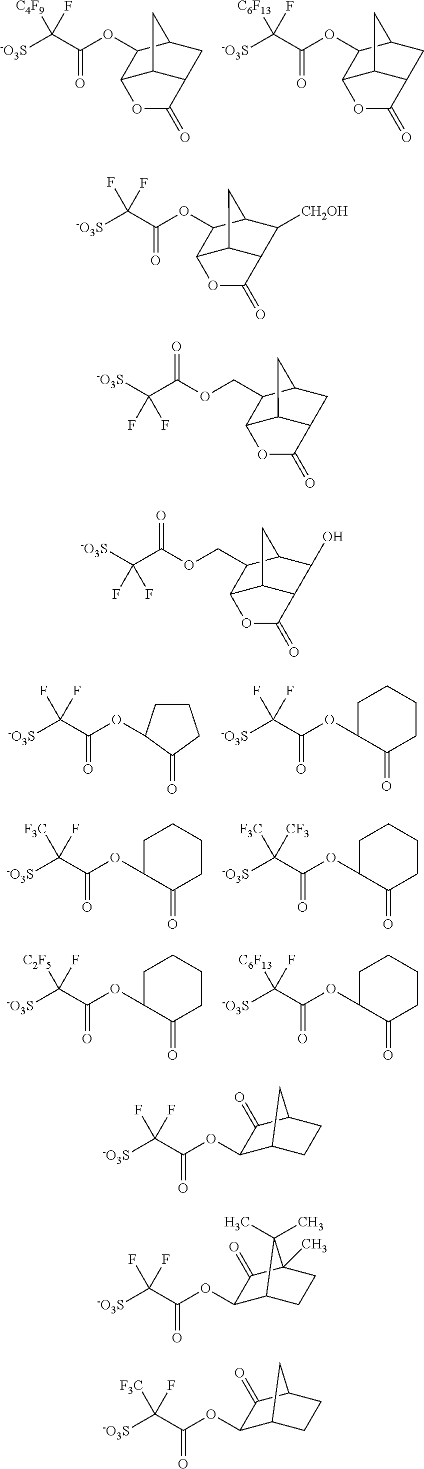

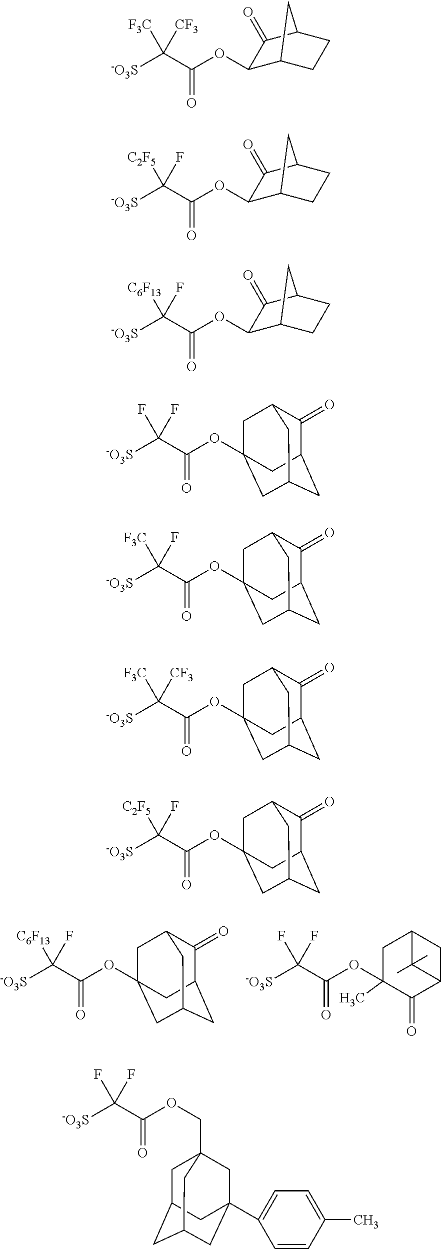

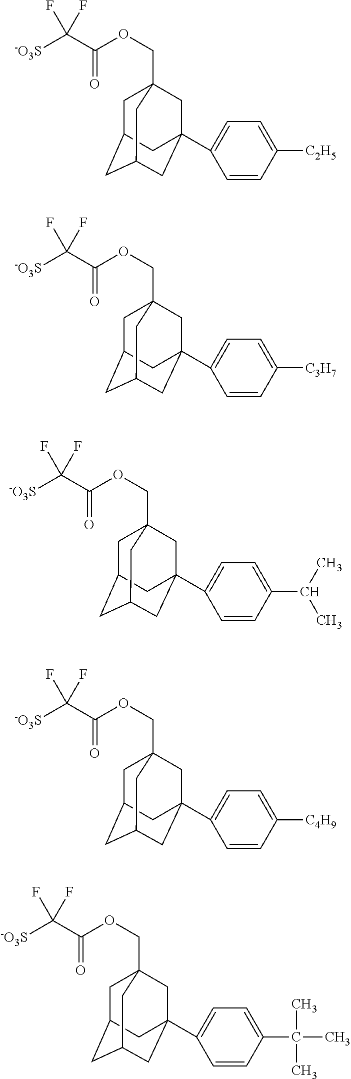

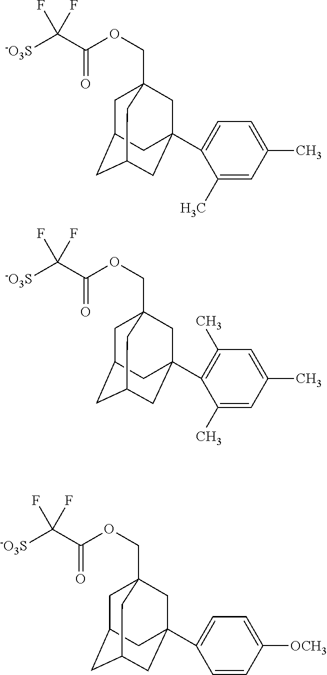

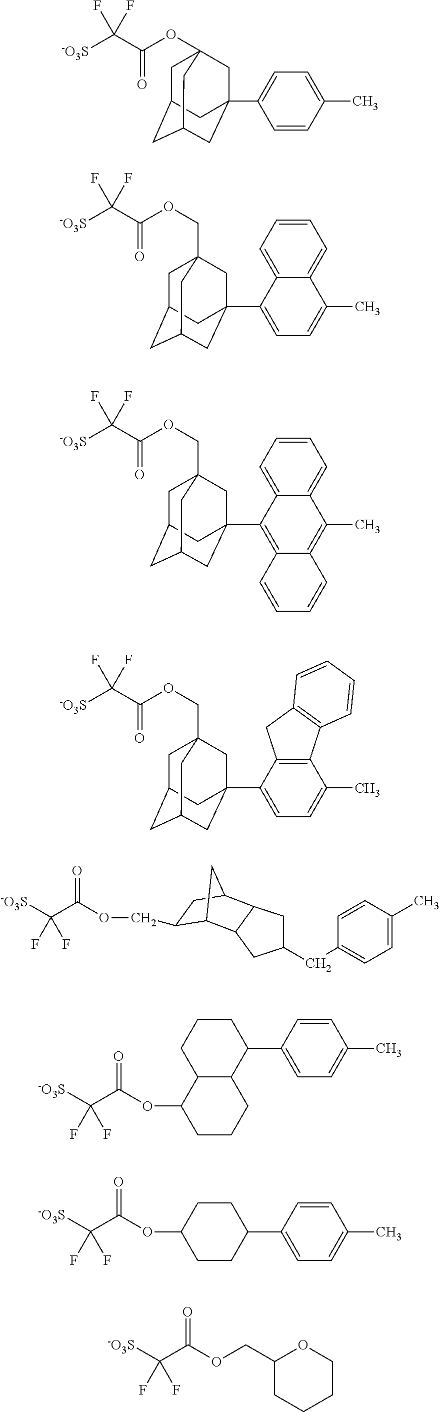

Examples of the anion part represented by the formula (IB) include the followings.

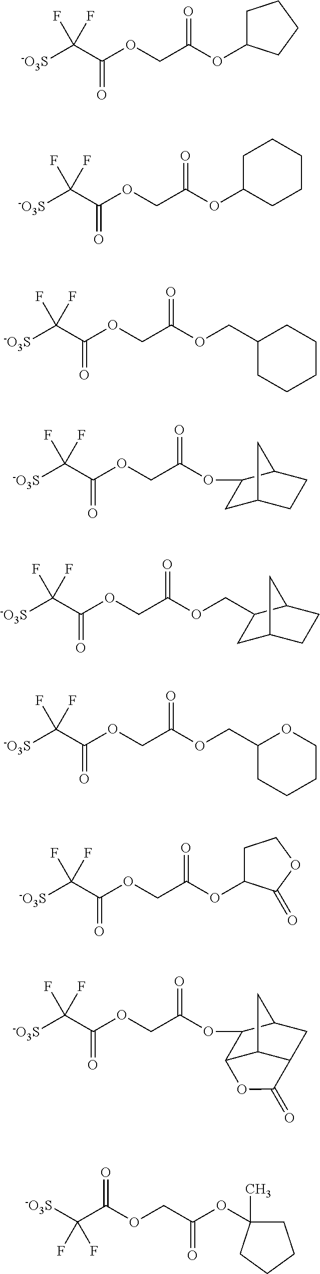

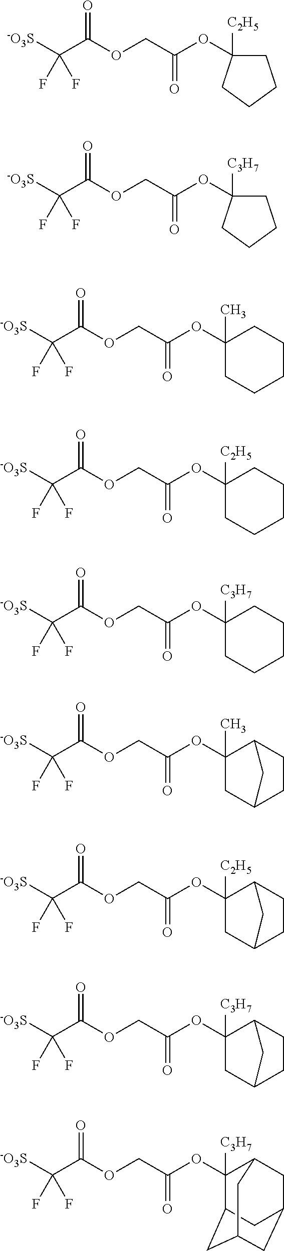

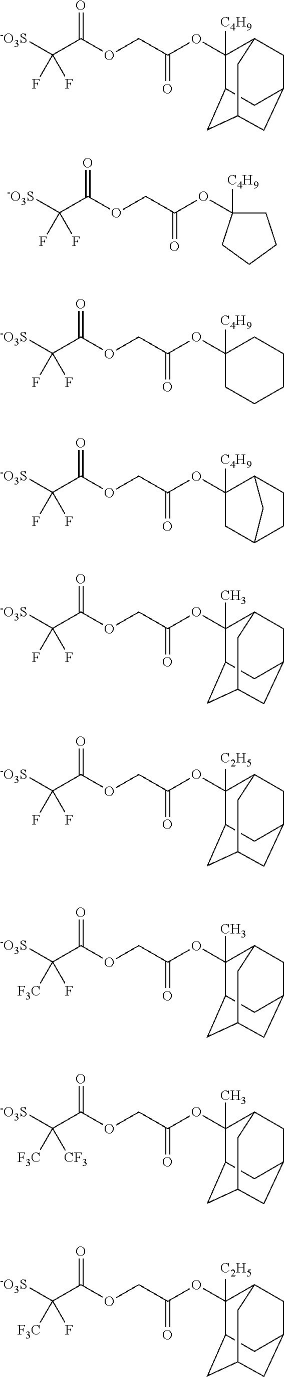

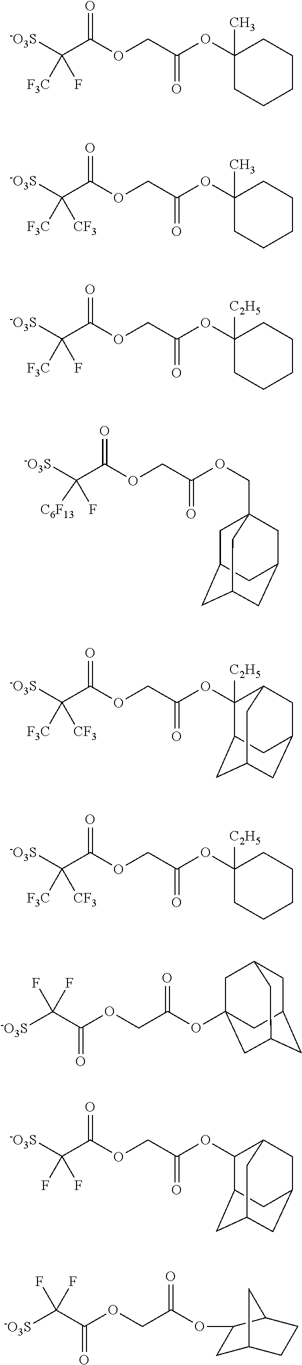

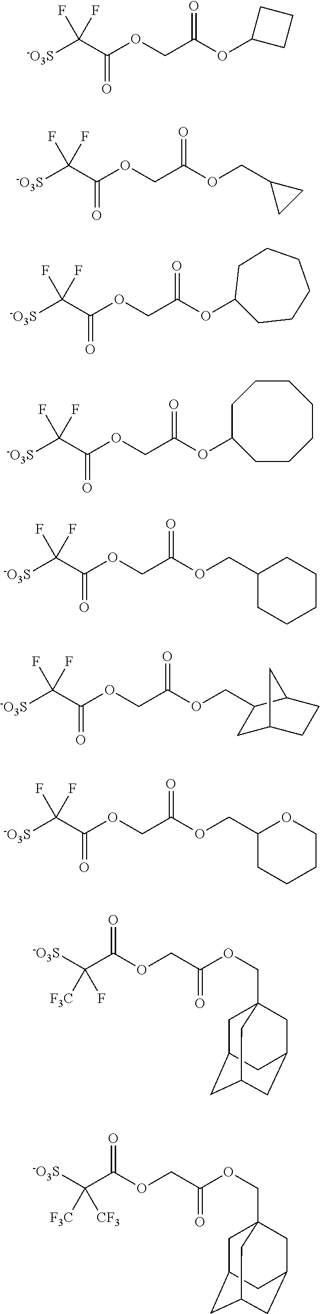

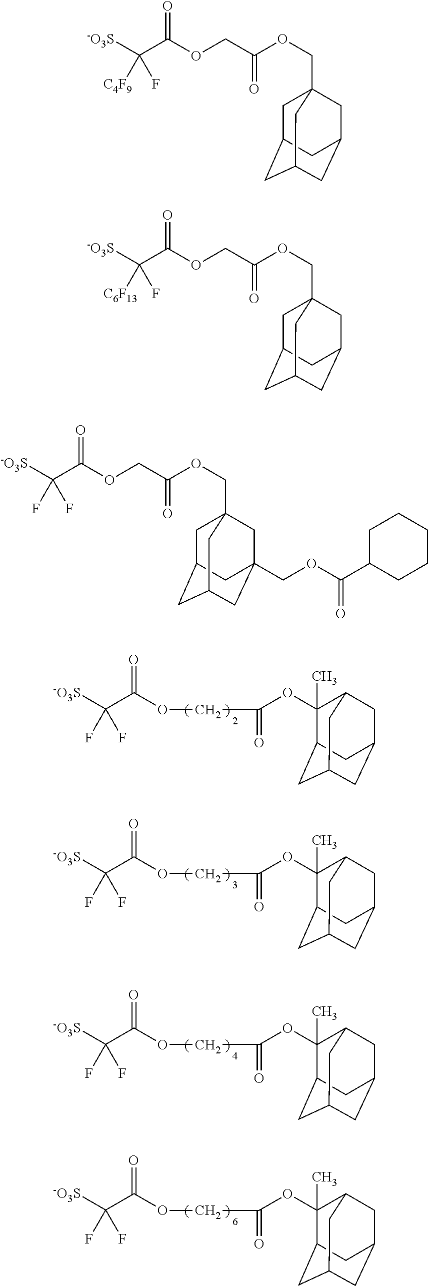

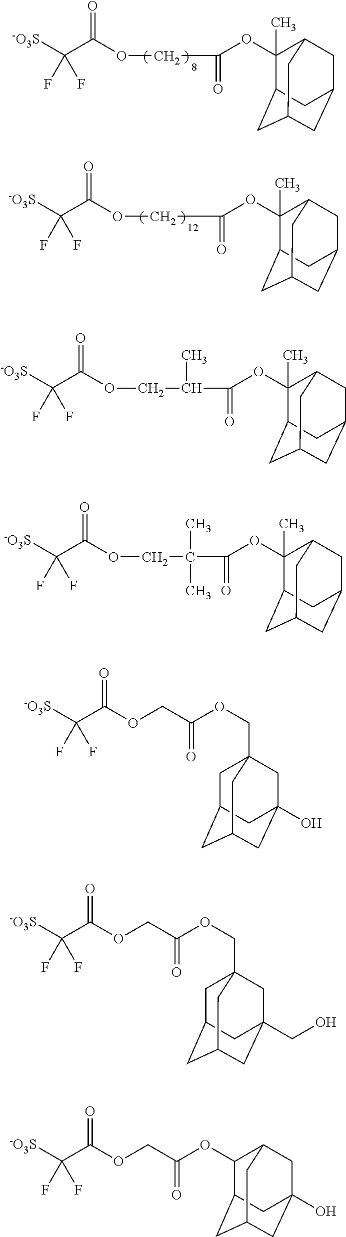

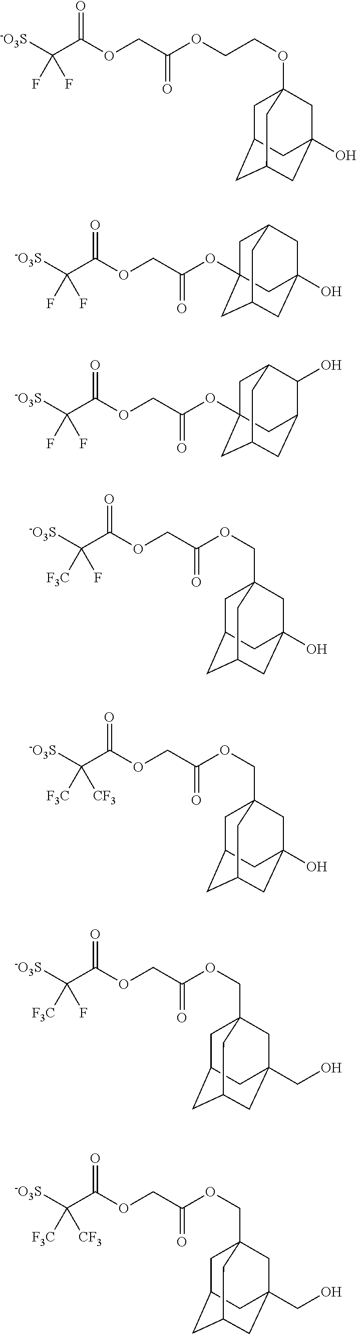

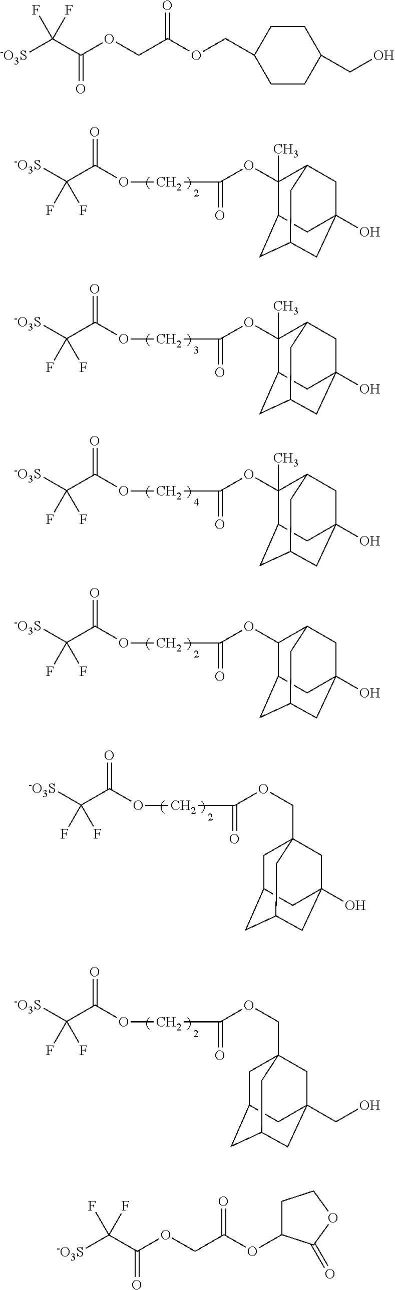

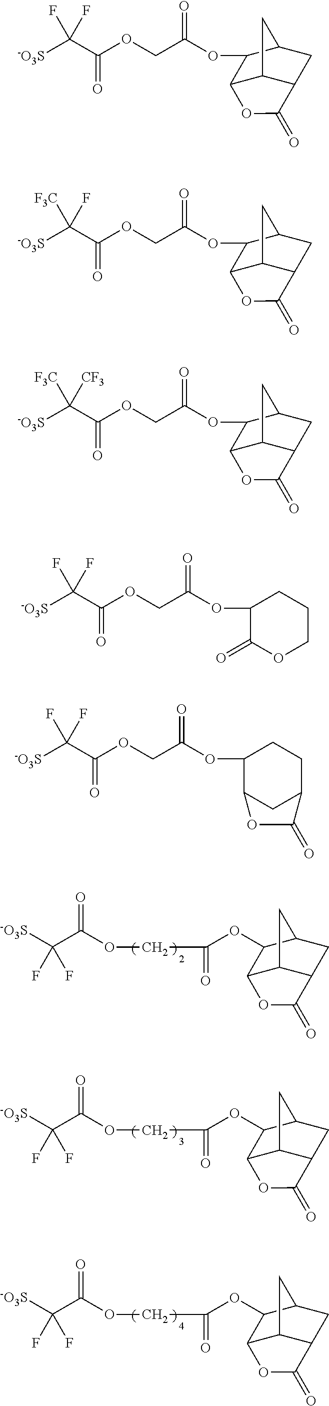

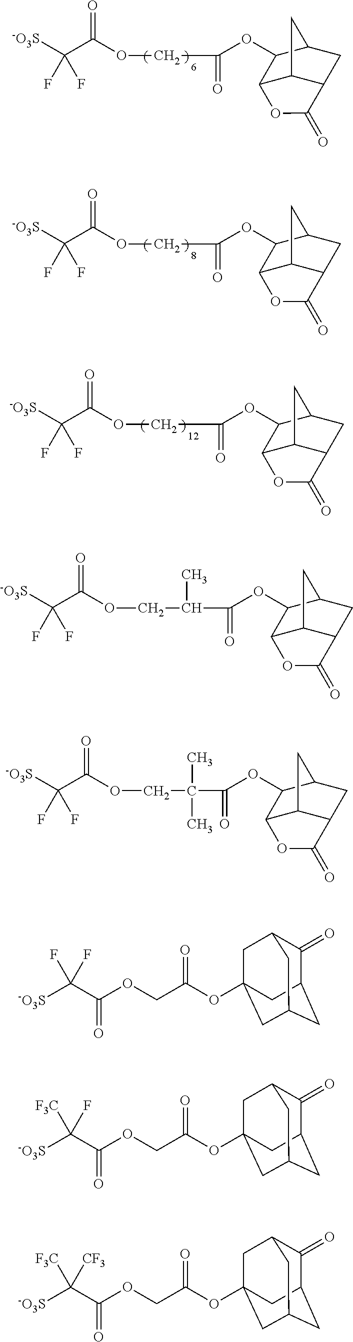

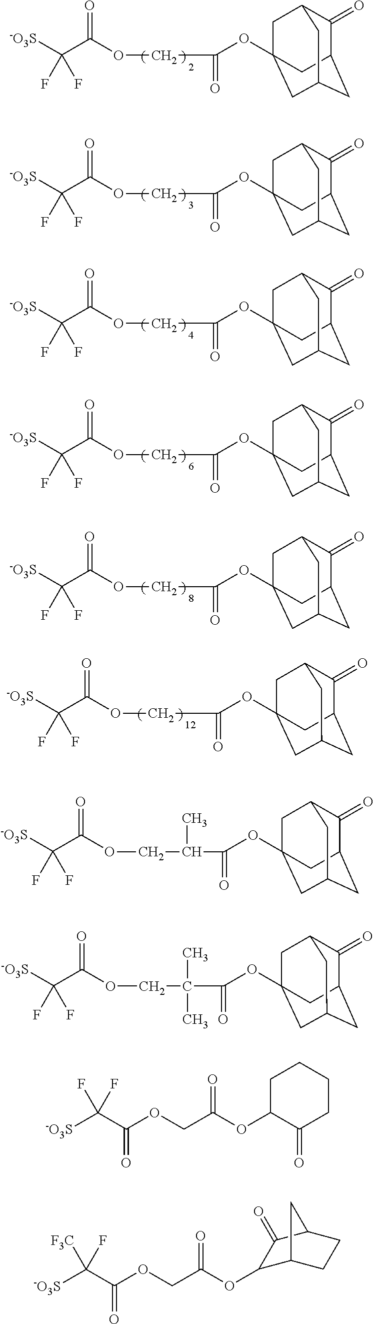

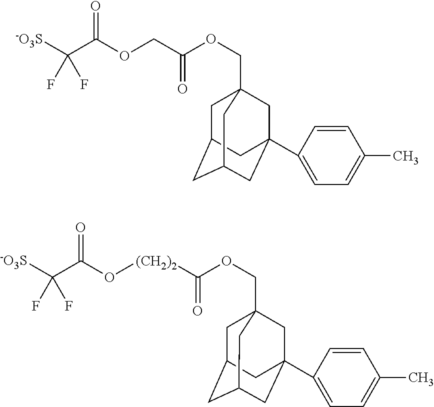

Examples of the anion part represented by the formula (IC) include the followings.

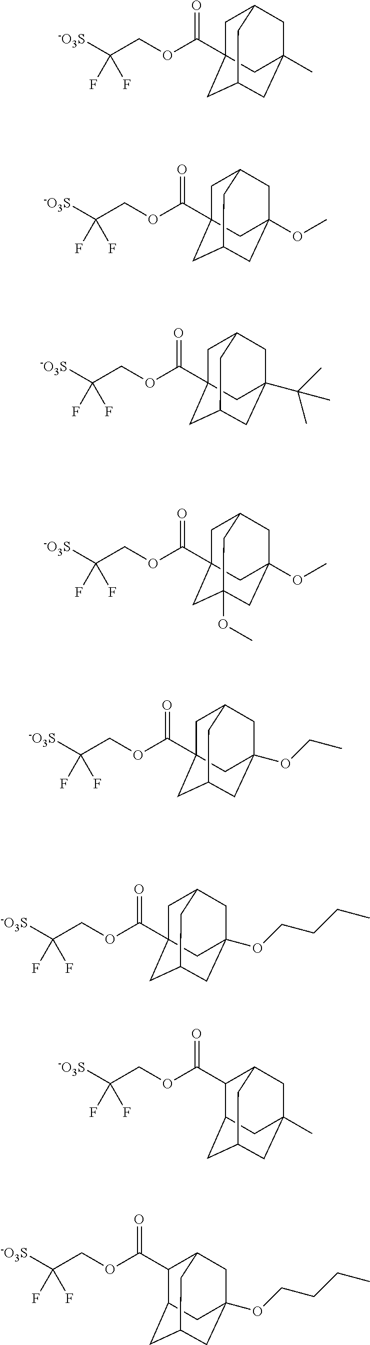

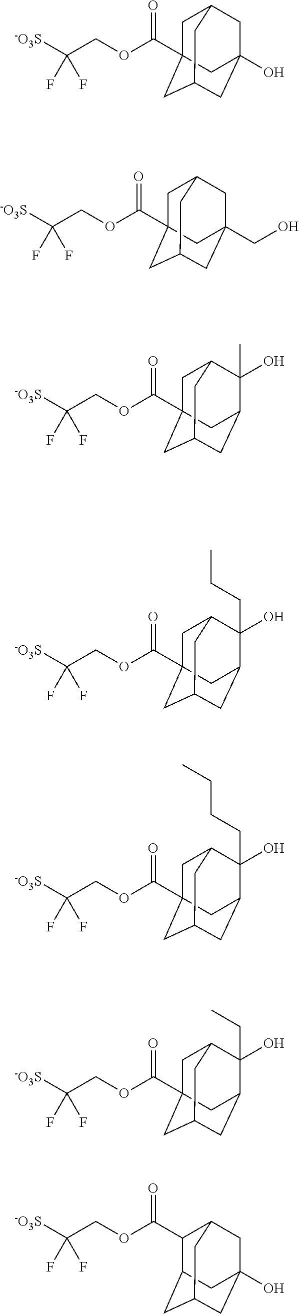

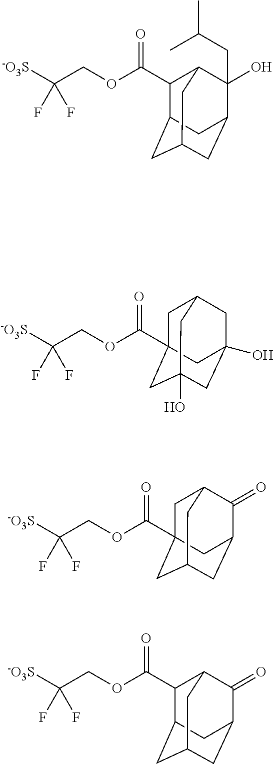

Examples of the anion part represented by the formula (ID) include the followings.

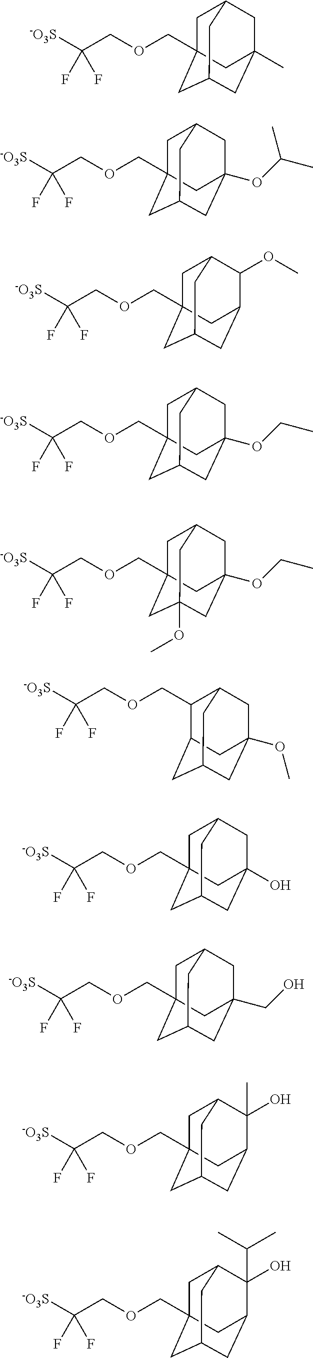

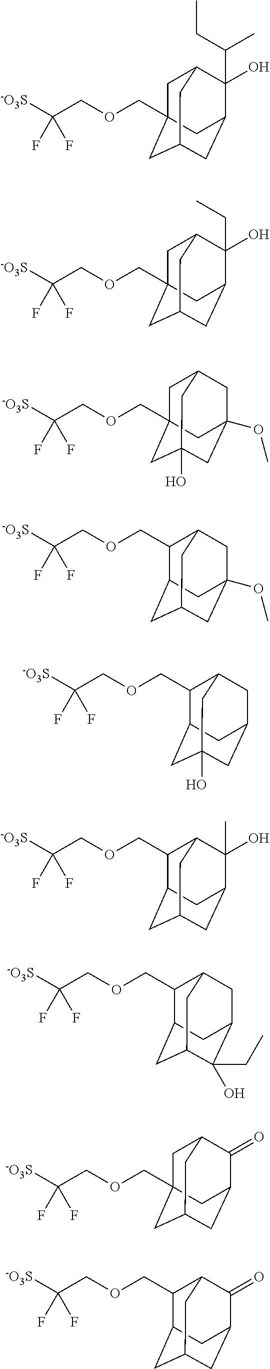

Examples of the cation part represented by Z⁺ of the salt represented by the formula (I) include cations represented by the formulae (IXa), (IXb), (IXc) and (IXd), and a cation represented by the formula (IXa) is preferable.

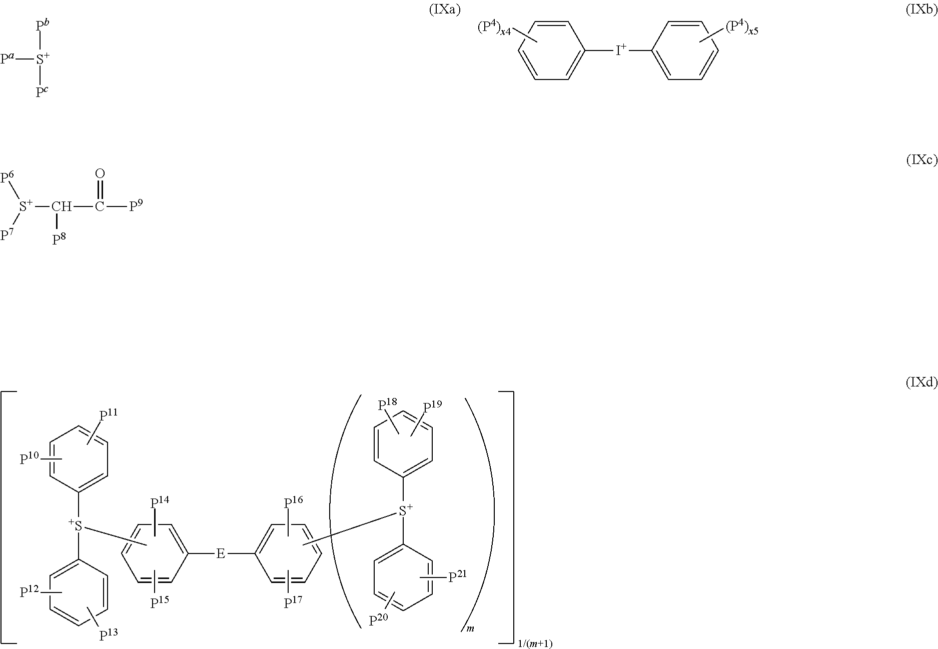

wherein P^{a}, P^{b} and P^{c} each independently represent a C1-C10 aliphatic hydrocarbon group which can have one or more substituents, a C4-C36 alicyclic hydrocarbon group which can have one or more substituents or a C6-C36 aromatic hydrocarbon group which can have one or more substituents, and P^{a} and P^{b} can be bonded each other to form a ring, and one or more methylene groups in the aliphatic hydrocarbon group and the alicyclic hydrocarbon group can be replaced by —S—, —CO— or —O—,
P⁴ and P⁵ are independently in each occurrence a hydrogen atom, a hydroxyl group, a C1-C12 alkyl group or a C1-C12 alkoxy group, x4 and x5 independently represents an integer of 1 to 5, and
P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group may be replaced by —CO—, —O— or —S—, and
P⁸ represents a hydrogen atom, P⁹ represents a C1-C12 alkyl group, a C3-C12 cycloalkyl group or a C6-C20 aromatic group which may be substituted, or P⁸ and P⁹ are bonded each other to form a divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, and
P¹⁰, P¹¹, P¹², P¹³, P¹⁴, P¹⁵, P¹⁶, P¹⁷, P¹⁸, P¹⁹, P²⁰ and P²¹ each independently represent a hydrogen atom, a hydroxyl group, a C1-C12 alkyl group or a C1-C12 alkoxy group, E represents a sulfur atom or an oxygen atom and m represents 0 or 1.

Examples of the aliphatic hydrocarbon group include the same as described above, and an alkyl group is preferable. This aliphatic hydrocarbon group can have one or more substituents, and examples of the substituent include a hydroxyl group, a C3-C12 alicyclic hydrocarbon group and a C1-C12 alkoxy group.

Examples of the alicyclic hydrocarbon group include the same as described above, and a C3-C30 alicyclic hydrocarbon group is preferable. This alicyclic hydrocarbon group can have one or more substituents, and examples of the substituent include a hydroxyl group, a C1-C12 alkyl group and a C1-C12 alkoxy group.

Examples of the aromatic hydrocarbon group include a phenyl group, a naphthyl group and an anthryl group, and examples of the substituent include a hydroxyl group, a C1-C12 alkyl group and a C1-C12 alkoxy group.

Examples of the alkoxy group include a methoxy group, an ethoxy group, a propoxy group, an isopropoxy group, a butoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group.

Examples of the cycloalkyl group include a cyclohexyl group and an adamantyl group.

Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and an oxybisethylenesulfonio group.

Examples of the C6-C20 aromatic group include a phenyl group, a tolyl group, a xylyl group, a tert-butylphenyl group and a naphthyl group. Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include the followings.

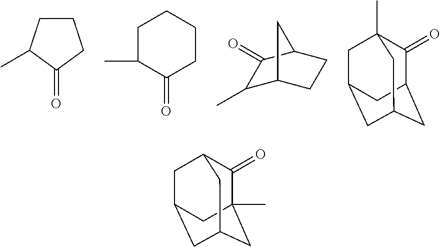

The cation represented by the formula (IXa) wherein P^{a}, P^{b} and P^{c} each independently represent a C6-C20 aromatic hydrocarbon group which can have one or more substituents selected from the group consisting of a hydroxyl group, a C1-C12 alkyl group, and a C1-C12 alkoxy group, is preferable, and a cation represented by the formula (IXaa):

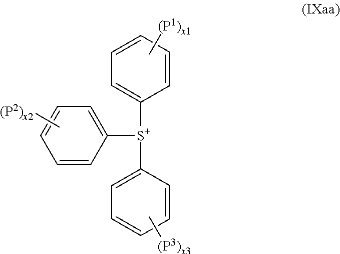

wherein P¹, P² and P³ independently each represent a hydrogen atom, a hydroxyl group, a C1-C12 alkyl group, a C1-C12 alkoxy group, or a C4-C36 alicyclic hydrocarbon group, and one or more hydrogen atoms of the C4-C36 alicyclic hydrocarbon group can be replaced by a halogen atom, a hydroxyl group, a C1-C12 alkyl group, a C1-C12 alkoxy group, a C6-C12 aryl group, a C7-C12 aralkyl group, a glycidyloxy group or a C2-C4 acyl group, and x1, x2 and x3 independently each represent an integer of 1 to 5, and any two of P¹, P² and P³ can be bonded each other to form a ring, is more preferable. Preferable examples of the alycyclic hydrocarbon group include a group having an adamantane ring or an isobornane ring, and a 2-alkyl-2-adamantyl group, a 1-(1-adamantyl)-1-alkyl group and an isobornyl group are more preferable.

Among them, a cation is preferably a triarylsulfonium cation. Examples of the salt represented by the formula (I) include a salt wherein the anion part is any one of the above-mentioned anion part and the cation part is any one of the above-mentioned cation part.

Examples of the cation represented by the formula (IXaa) include the followings.

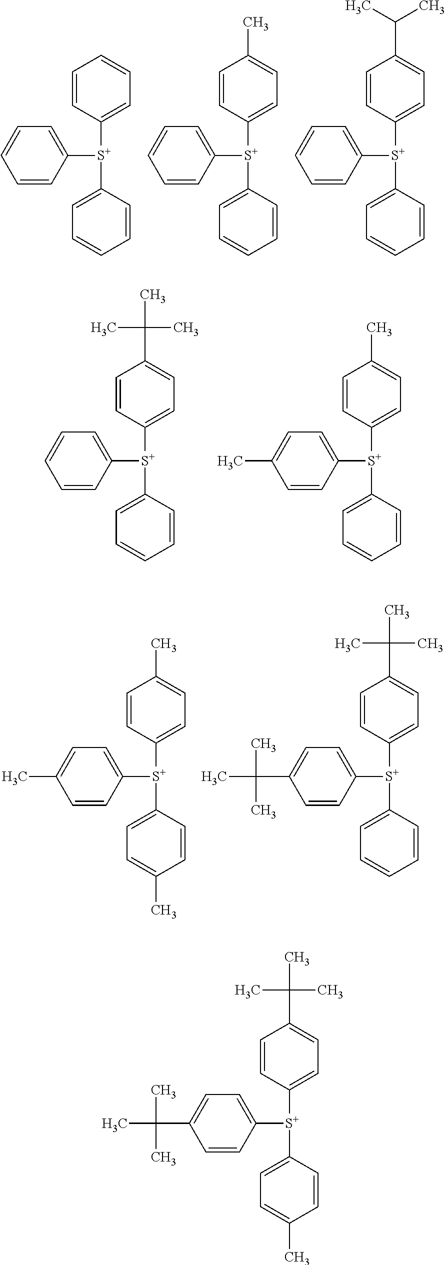

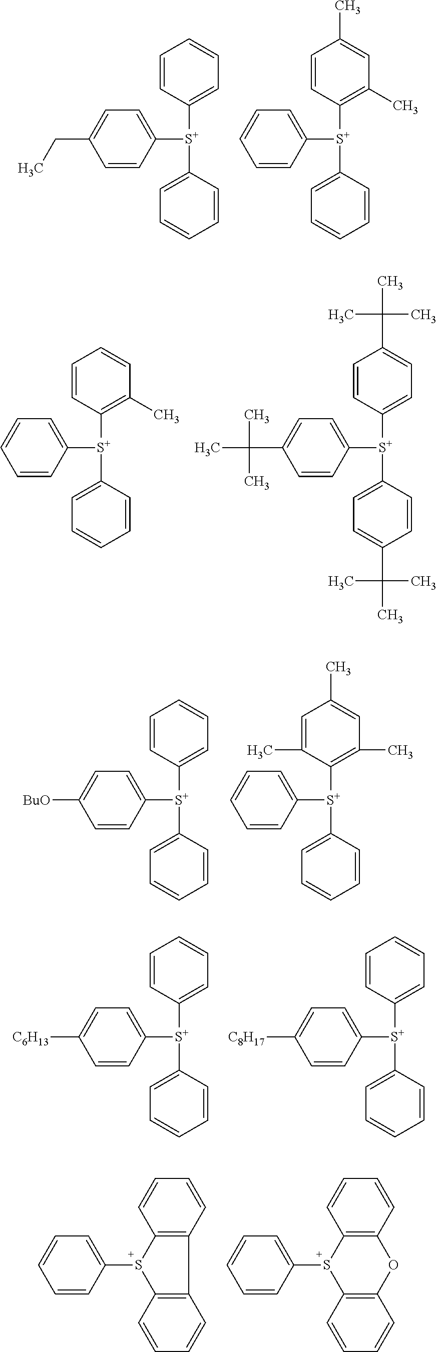

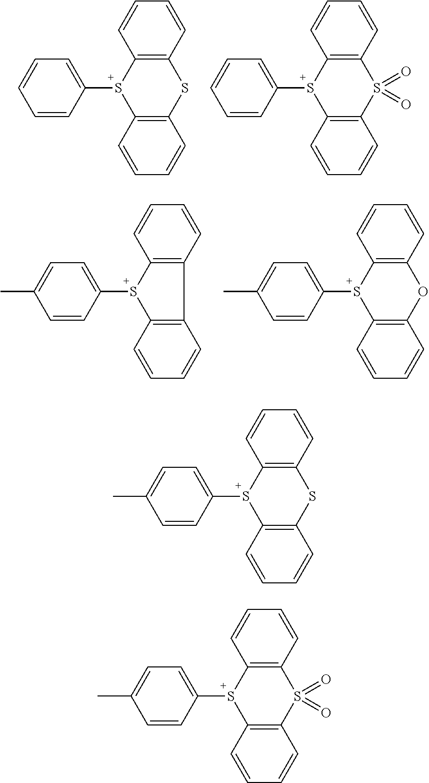

Among them, a cation represented by the formula (IXaaa):

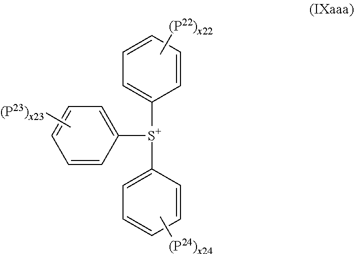

wherein P²², P²³ and P²⁴ independently each represent a hydrogen atom, a hydroxyl group, a C1-C12 alkyl group or a C1-C12 alkoxy group and any two of P²², P²³ and P²⁴ can be bonded each other to form a ring and x22, X23 and x24 independently each represent an integer of 1 to 5, is preferable. The ring formed by bonding any two of P²², P²³ and P²⁴ may be an alicyclic ring or an aromatic ring.

Examples of the cation represented by the formula (IXb) include the followings.

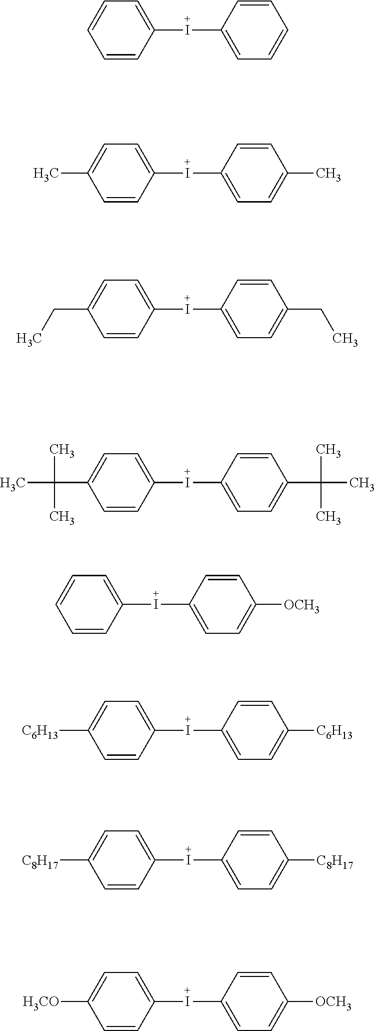

Examples of the cation represented by the formula (IXc) include the following.

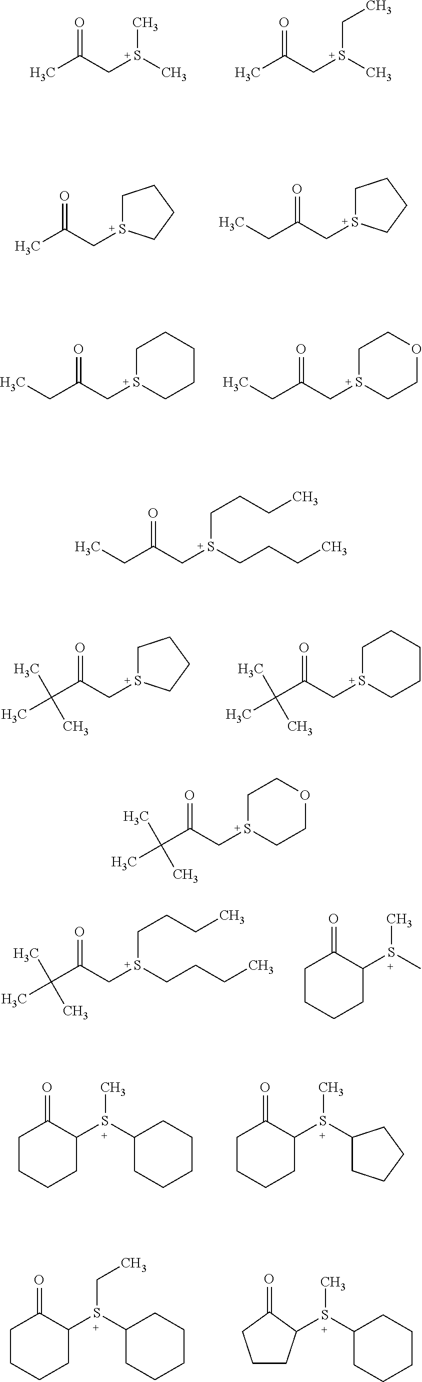

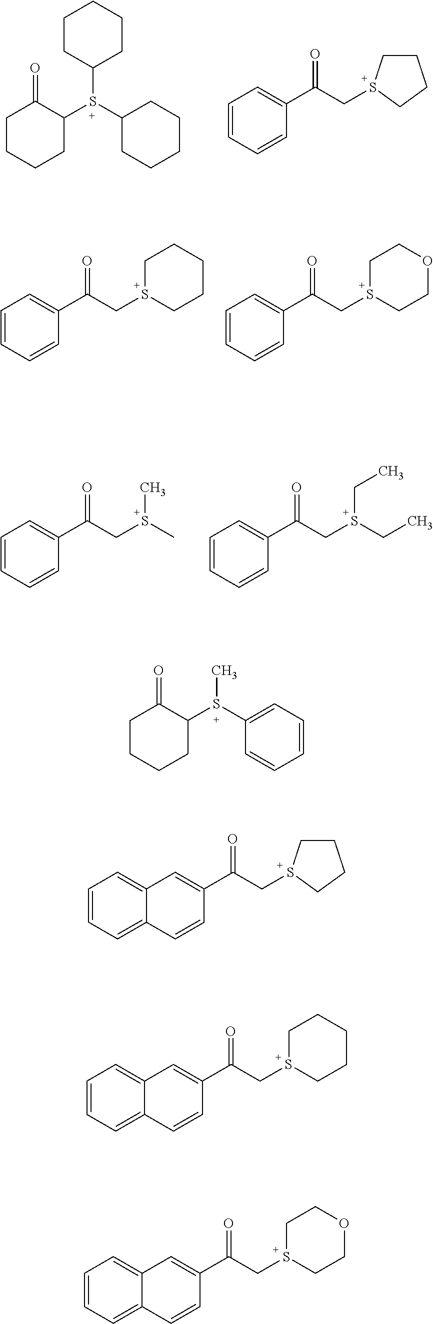

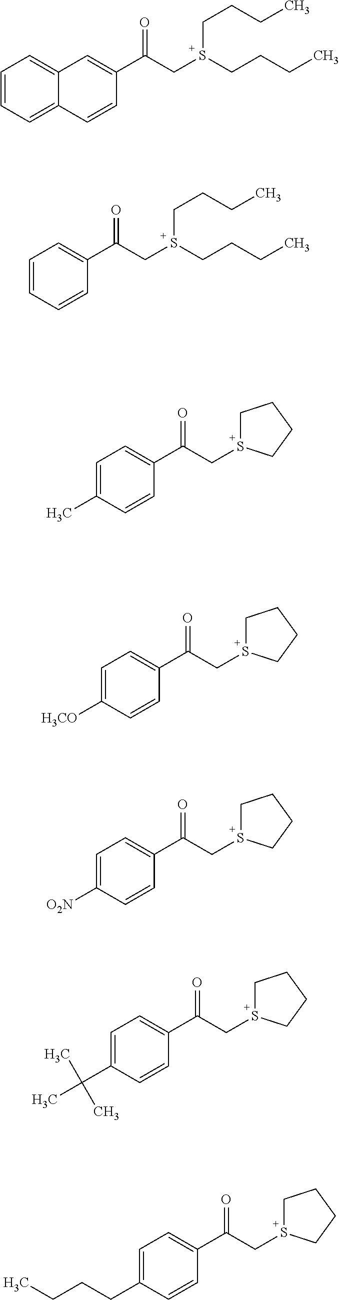

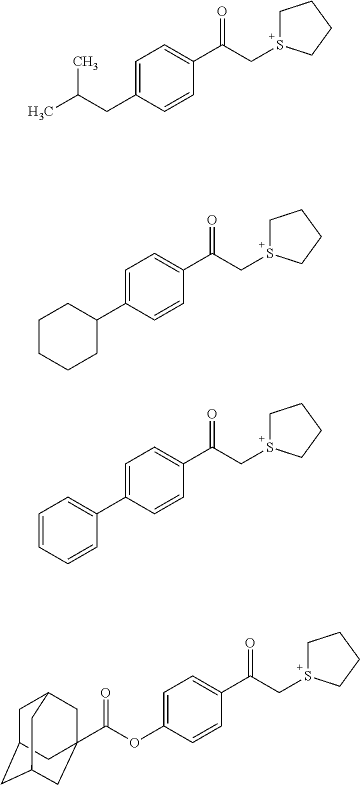

Examples of the cation represented by the formula (IXd) include the following.

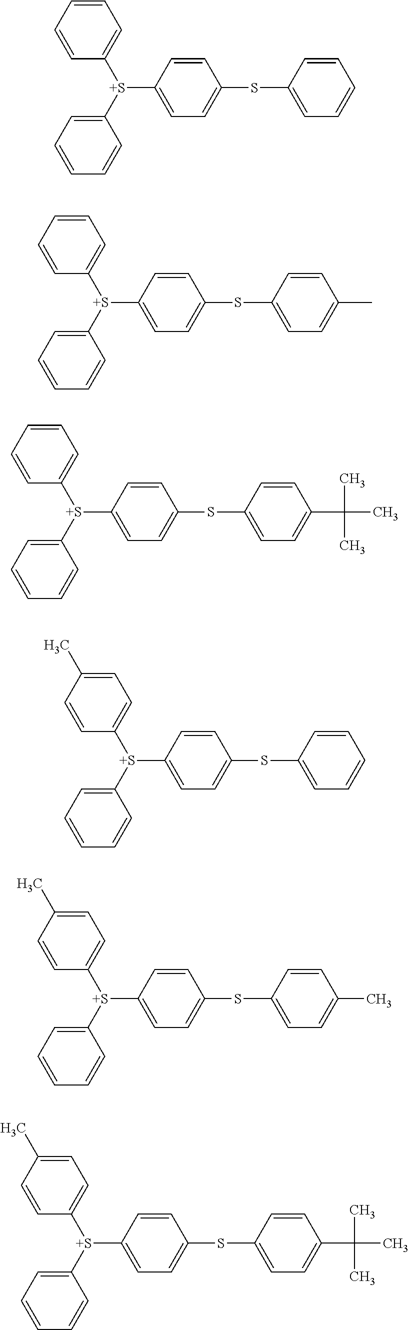

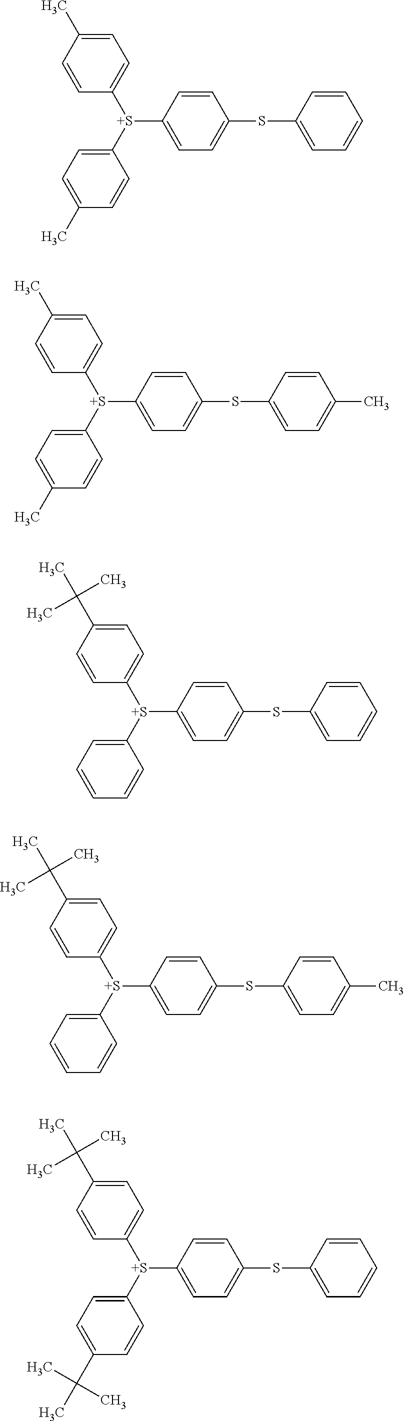

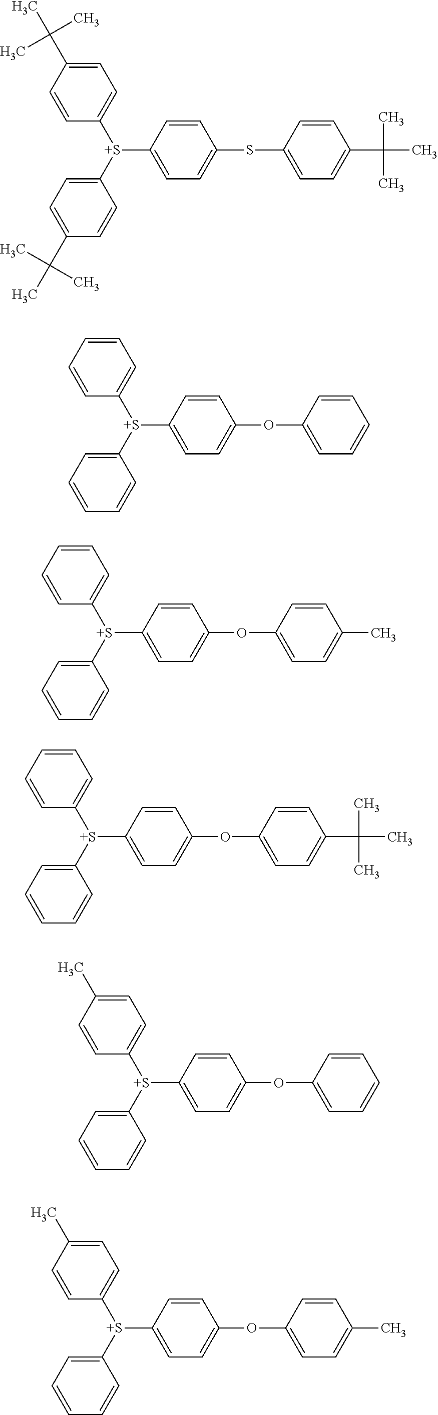

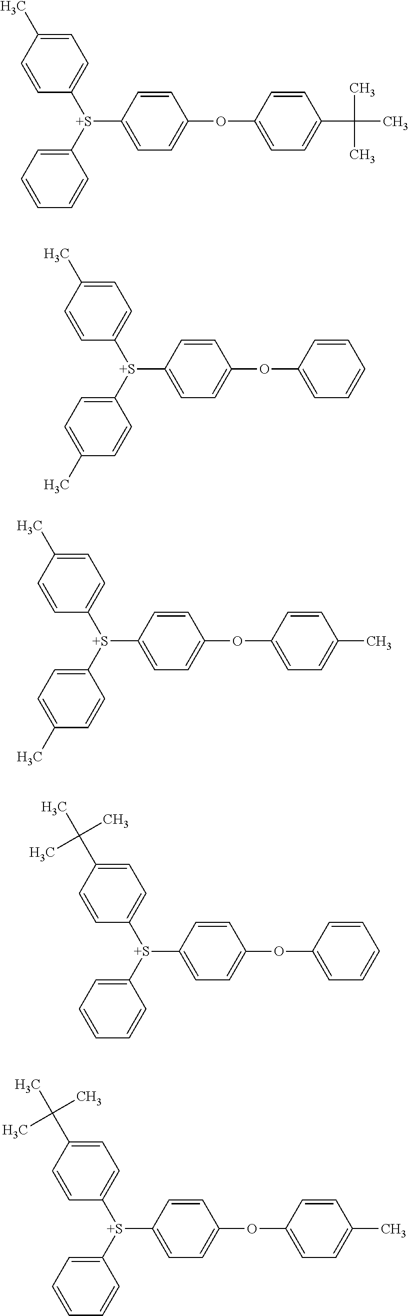

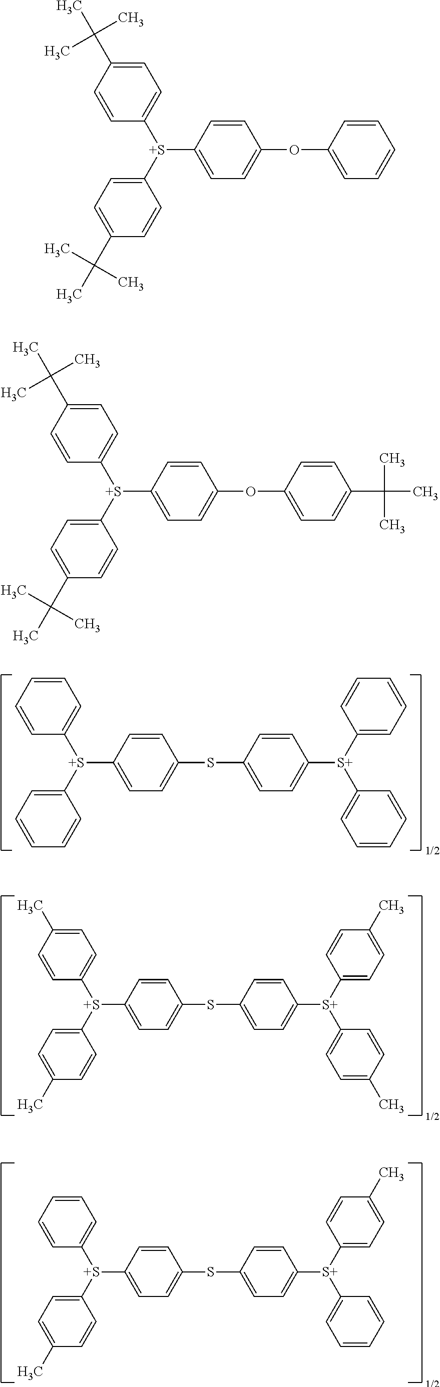

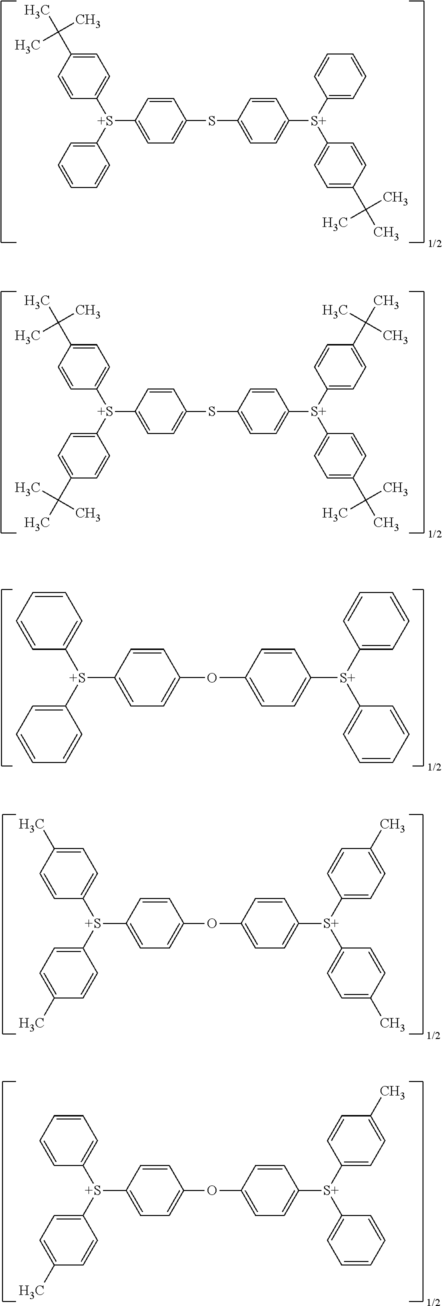

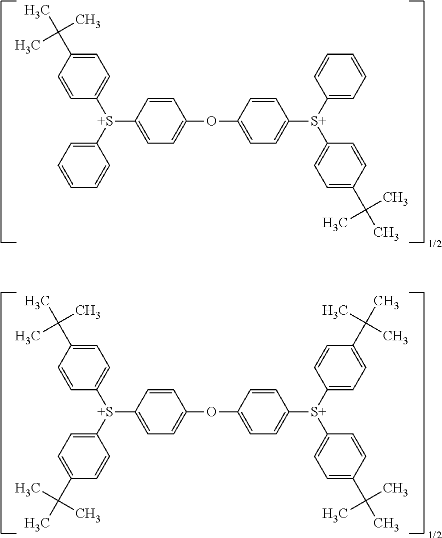

Among them, a triarylsulfonium cation is preferable.

Examples of the salt represented by the formula (I) include a salt consisting of any one of the above-mentioned anion and any one of the above-mentioned cation.

Specific examples of the salt represented by the formula (I) include salts represented by the formulae (Xa) to (Xi):

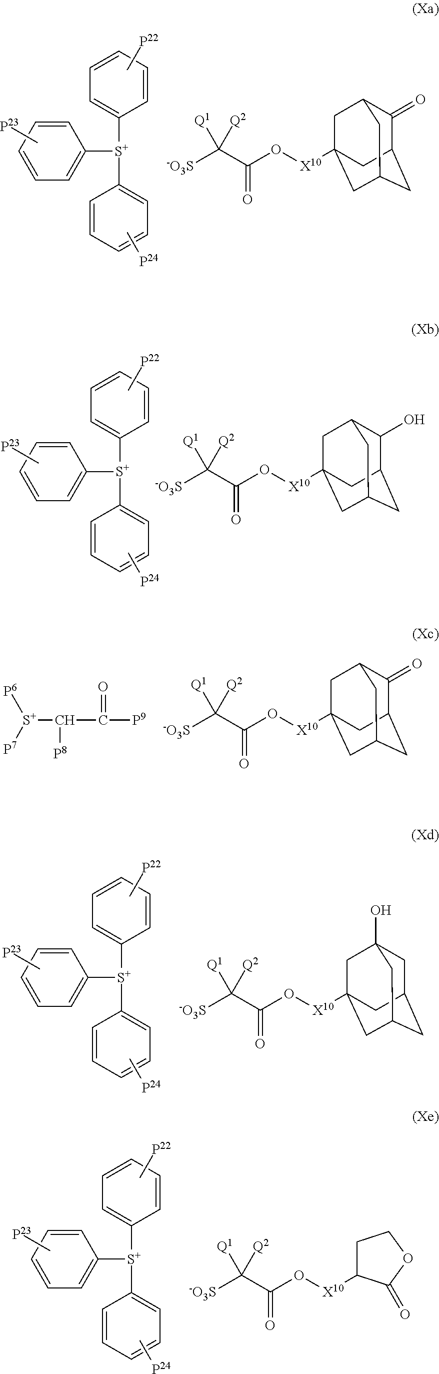

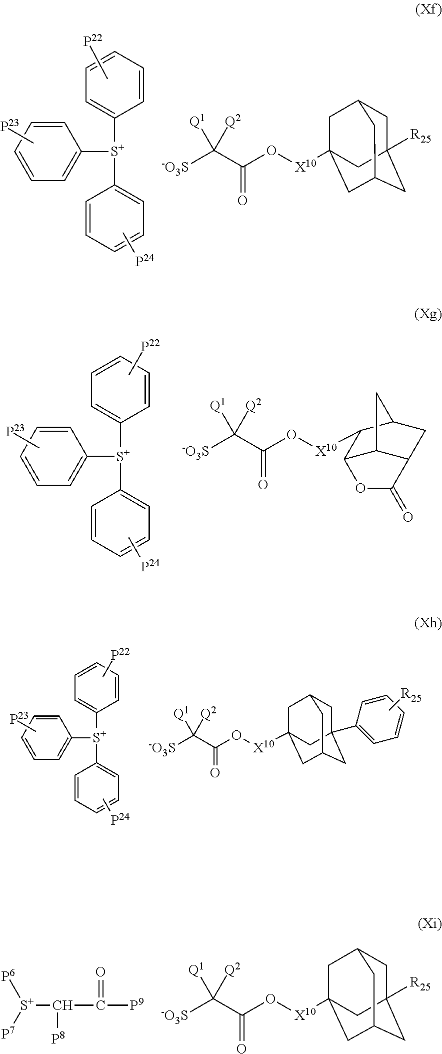

wherein P²⁵ independently each represent a hydrogen atom, a C1-C4 aliphatic hydrocarbon group or a C4-C36 alicyclic hydrocarbon group, and P²², P²³, P²⁴, P⁶, P⁷, P⁸, P⁹, Q¹, Q² and X¹⁰ are the same as defined above.

Preferable examples of the salt represented by the formula (I) include the followings.

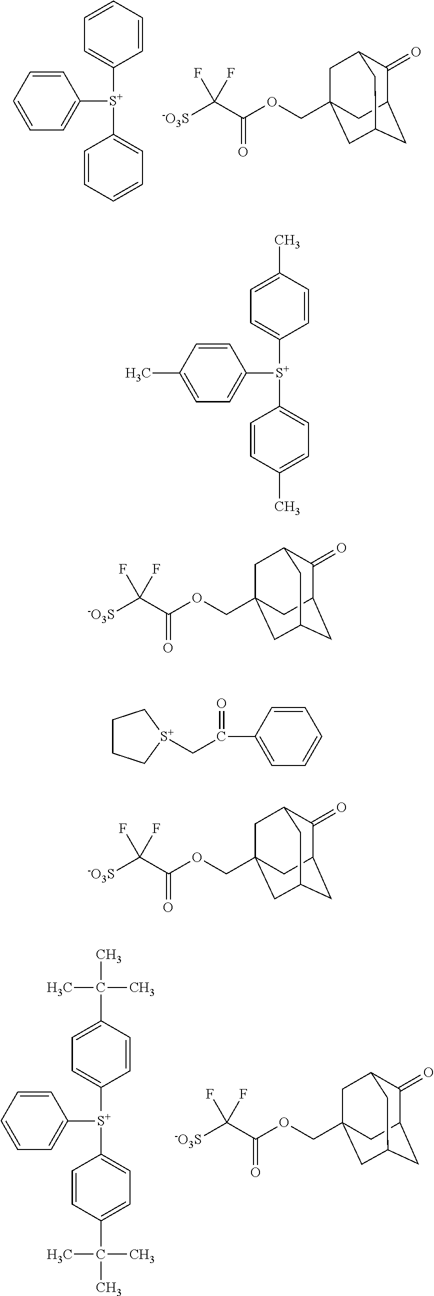

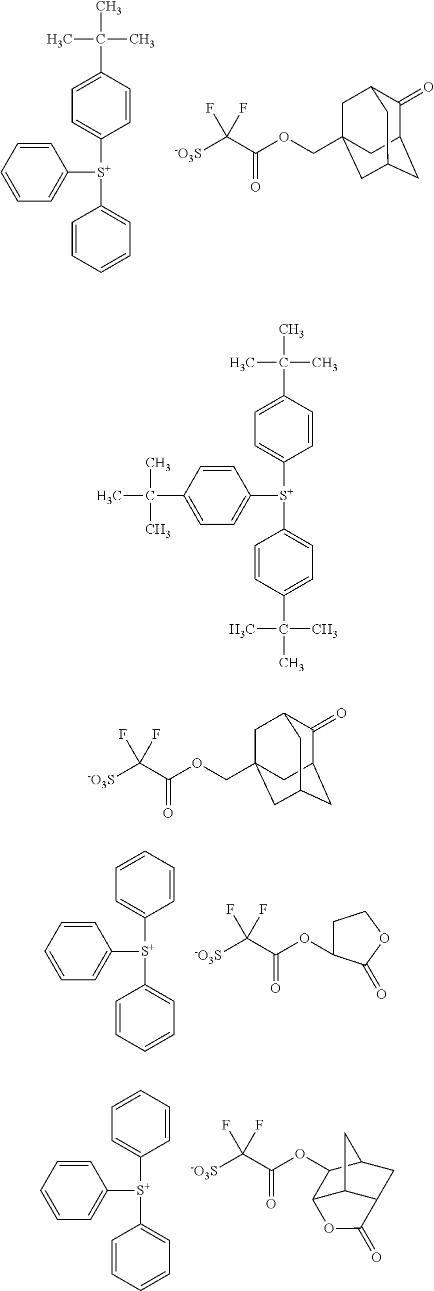

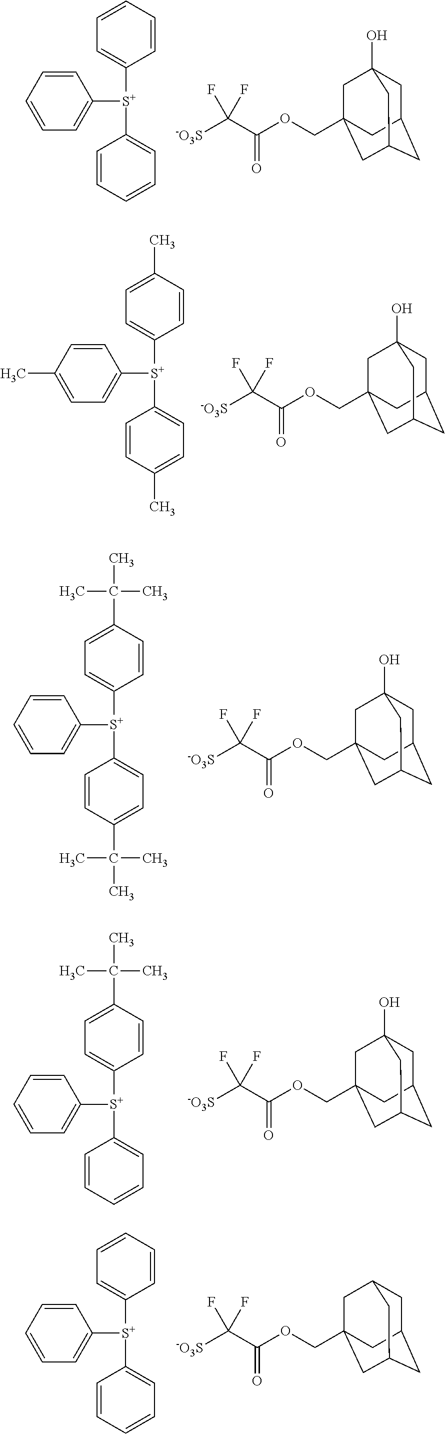

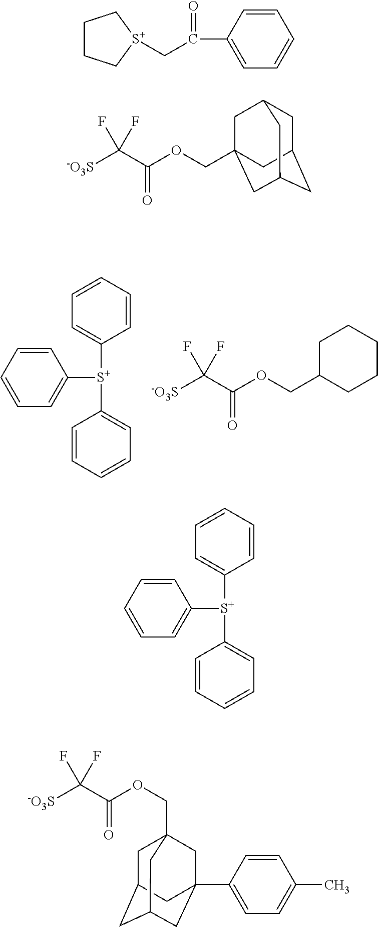

Among them, the salt represented by the formula (I) wherein the cation part is the cation part represented by the formula (IXaaa) in which P²², P²³ and P²⁴ are hydrogen atoms and the anion part is the anion part selected from the group consisting of the specific examples of the anion part represented by the formula (IA) cited above is preferable.

Two or more kinds of the salt represented by the formula (I) can be used in combination.

The salt represented by the formula (I) can be produced, for example, by the method described in JP 2008-209917 A.

The content of the acid generator is usually 1 to 20 parts by weight and preferably 1 to 15 parts by weight per 100 parts by weight of the resin component.

In the present resist composition, performance deterioration caused by inactivation of acid which occurs due to post exposure delay can be diminished by adding an organic base compound, particularly a nitrogen-containing organic base compound as a quencher.

Specific examples of the nitrogen-containing organic base compound include an amine compound represented by the following formulae:

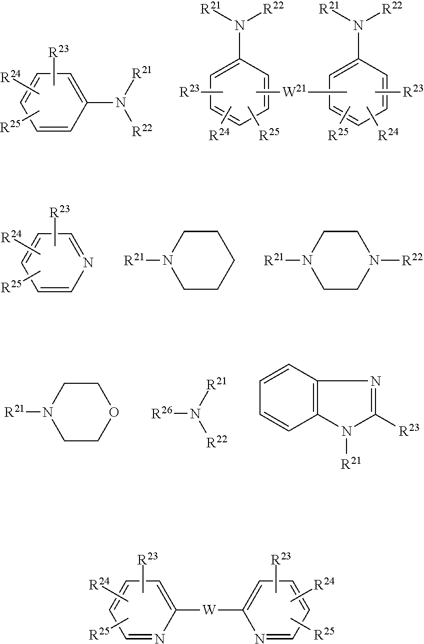

wherein R²¹ and R²² independently represent a hydrogen atom, a C1-C6 alkyl group, a C5-C10 cycloalkyl group or a C6-C10 aryl group, and the alkyl, cycloalkyl and aryl groups can have one or more substituents selected from the group consisting of a hydroxyl group, a C1-C6 alkoxy group which can have one or more C1-C6 alkoxy groups, and an amino group which can have one or two C1-C4 alkyl groups, R²³ and R²⁴ independently represent a hydrogen atom, a C1-C6 alkyl group, a C5-C10 cycloalkyl group, a C6-C10 aryl group or a C1-C6 alkoxy group, and the alkyl, cycloalkyl, aryl and alkoxy groups can have one or more substituents selected from the group consisting of a hydroxyl group, an amino group which can have one or two C1-C4 alkyl groups, and a C1-C6 alkoxy group, or R²³ and R²⁴ are bonded each other together with the carbon atoms to which they are bonded to form an aromatic ring,
R²⁵ represent a hydrogen atom, a C1-C6 alkyl group, a C5-C10 cycloalkyl group, a C6-C10 aryl group, a C1-C6 alkoxy group or a nitro group, and the alkyl, cycloalkyl, aryl and alkoxy groups can have one or more substituents selected from the group consisting of a hydroxyl group, an amino group which can have one or two C1-C4 alkyl groups, and a C1-C6 alkoxy group,
R²⁶ represents a C1-C6 alkyl group or a C5-C10 cycloalkyl group, and the alkyl and cycloalkyl groups can have one or more substituents selected from the group consisting of a hydroxyl group, an amino group which can have one or two C1-C4 alkyl groups, and a C1-C6 alkoxy group, and
W²¹ represents —CO—, —NH—, —S—, —S—S—, a C2-C6 alkylene group, and a quaternary ammonium hydroxide represented by the following formula:

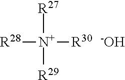

wherein R²⁷, R²⁸, R²⁹ and R³⁰ independently represent a C1-C6 alkyl group, a C5-C10 cycloalkyl group or a C6-C10 aryl group, and the alkyl, cycloalkyl and aryl groups can have one or more substituents selected from the group consisting of a hydroxyl group, an amino group which can have one or two C1-C4 alkyl groups, and a C1-C6 alkoxy group.

Examples of the amino group which can have one or two C1-C4 alkyl groups include an amino group, a methylamino group, an ethylamino group, a butylamino group, a dimethylamino group and a diethylamino group. Examples of the C1-C6 alkoxy group which can have one or more C1-C6 alkoxy groups include a methoxy group, an ethoxy group, a propoxy group, an isopropoxy group, a butoxy group, a tert-butoxy group, a pentyloxy group, a hexyloxy group and a 2-methoxyethoxy group.

Specific examples of the C1-C6 alkyl group which can have one or more substituents selected from the group consisting of a hydroxyl group, an amino group which can have one or two C1-C4 alkyl groups, and a C1-C6 alkoxy group which can have one or more C1-C6 alkoxy groups include a methyl group, an ethyl group, a propyl group, an isopropyl group, a butyl group, a tert-butyl group, a pentyl group, a hexyl group, a 2-(2-methoxyethoxy)ethyl group, a 2-hydroxyethyl group, a 2-hydroxypropyl group, a 2-aminoethyl group, a 4-aminobutyl group and a 6-aminohexyl group.

Specific examples of the C5-C10 cycloalkyl group which can have one or more substituents selected from the group consisting of a hydroxyl group, an amino group which can have one or two C1-C4 alkyl groups, and a C1-C6 alkoxy group include a cyclopentyl group, a cyclohexyl group, a cycloheptyl group and a cyclooctyl group.

Specific examples of the C6-C10 aryl group which can have one or more substituents selected from the group consisting of a hydroxyl group, an amino group which can have one or two C1-C4 alkyl groups, or a C1-C6 alkoxy group include a phenyl group and a naphthyl group.

Specific examples of the C1-C6 alkoxy group include a methoxy group, an ethoxy group, a propoxy group, an isopropoxy group, a butoxy group, a tert-butoxy group, a pentyloxy group and a hexyloxy group.

Specific examples of the C2-C6 alkylene group include an ethylene group, a trimethylene group and a tetramethylene group.

Specific examples of the amine compound include hexylamine, heptylamine, octylamine, nonylamine, decylamine, aniline, 2-methylaniline, 3-methylaniline, 4-methylaniline, 4-nitroaniline, 1-naphthylamine, 2-naphthylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 1,2-bis(4-pyridyl)ethylene, 2,2′-dipicolylamine and 3,3′-dipicolylamine.

Examples of the quaternary ammonium hydroxide include tetramethylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).

A hindered amine compound having a piperidine skeleton as disclosed in JP 11-52575 A1 can be also used as the quencher.

In the point of forming patterns having higher resolution, the quaternary ammonium hydroxide is preferably used as the quencher.

When the basic compound is used as the quencher, the present resist composition preferably includes 0.01 to 1% by weight of the basic compound based on sum of solid component.

The present resist composition can contain, if necessary, a small amount of various additives such as a sensitizer, a dissolution inhibitor, other polymers, a surfactant, a stabilizer and a dye as long as the effect of the present invention is not prevented.

The present resist composition is usually in the form of a resist liquid composition in which the above-mentioned ingredients are dissolved in a solvent and the resist liquid composition is applied onto a substrate such as a silicon wafer by a conventional process such as spin coating. The solvent used is sufficient to dissolve the above-mentioned ingredients, have an adequate drying rate, and give a uniform and smooth coat after evaporation of the solvent. Solvents generally used in the art can be used.

Examples of the solvent include a glycol ether ester such as ethyl cellosolve acetate, methyl cellosolve acetate and propylene glycol monomethyl ether acetate; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

A photoresist pattern can be produced by the following steps (1) to (5):
(1) a step of applying the photoresist composition of the present invention on a substrate,
(2) a step of forming a photoresist film by conducting drying,
(3) a step of exposing the photoresist film to radiation,
(4) a step of baking the exposed photoresist film, and
(5) a step of developing the baked photoresist film with an alkaline developer, thereby forming a photoresist pattern.

The applying of the photoresist composition on a substrate is usually conducted using a conventional apparatus such as spin coater.

The formation of the photoresist film is usually conducted using a heating apparatus such as hot plate or a decompressor, and the heating temperature is usually 50 to 200° C., and the operation pressure is usually 1 to 1.0*10⁵ Pa.

The photoresist film obtained is exposed to radiation using an exposure system. The exposure is usually conducted through a mask having a pattern corresponding to the desired photoresist pattern. Examples of the exposure source include a light source radiating laser light in a UV-region such as a KrF excimer laser (wavelength: 248 nm), an ArF excimer laser (wavelength: 193 nm) and a F₂ laser (wavelength: 157 nm), and a light source radiating harmonic laser light in a far UV region or a vacuum UV region by wavelength conversion of laser light from a solid laser light source (such as YAG or semiconductor laser).

The temperature of baking of the exposed photoresist film is usually 50 to 200° C., and preferably 70 to 150° C.

The development of the baked photoresist film is usualt carried out using a development apparatus. The alkaline developer used may be any one of various alkaline aqueous solution used in the art. Generally, an aqueous solution of tetramethylammonium hydroxide or (2-hydroxyethyl)trimethylammonium hydroxide (commonly known as “choline”) is often used. After development, the photoresist pattern formed is preferably washed with ultrapure water, and the remained water on the photoresist pattern and the substrate is preferably removed.

The salt of the present invention and the polymer of the present invention are suitable components of a photoresist composition, and the photoresist composition of the present invention provides a photoresist pattern showing good resolution and good focus margin, and therefore, the photoresist composition of the present invention is suitable for ArF excimer laser lithography, KrF excimer laser lithography, ArF immersion lithography, EUV (extreme ultraviolet) lithography, EUV immersion lithography and EB (electron beam) lithography. Further, the photoresist composition of the present invention can be used for an immersion lithography and for a dry lithography. Furthermore, the photoresist composition of the present invention can be also used for a double imaging lithography.

### EXAMPLES

The present invention will be described more specifically by Examples, which are not construed to limit the scope of the present invention.

The “%” and “part(s)” used to represent the content of any component and the amount of any material used in the following examples and comparative examples are on a weight basis unless otherwise specifically noted. The weight-average molecular weight of any material used in the following examples is a value found by gel permeation chromatography [HLC-8120GPC Type, Column (Three Columns with guard column): TSKgel Multipore HXL-M, manufactured by TOSOH CORPORATION, Solvent: Tetrahydrofuran, Flow rate: 1.0 mL/min., Detector: RI detector, Column temperature: 40° C., Injection volume: 100 μL] using standard polystyrene as a standard reference material. Structures of compounds were determined by NMR (GX-270 Type or EX-270 Type, manufactured by JEOL LTD.) and mass spectrometry (Liquid Chromatography: 1100 Type, manufactured by AGILENT TECHNOLOGIES LTD., Mass Spectrometry: LC/MSD Type or LC/MSD TOF Type, manufactured by AGILENT TECHNOLOGIES LTD.).

### Reference Example 1

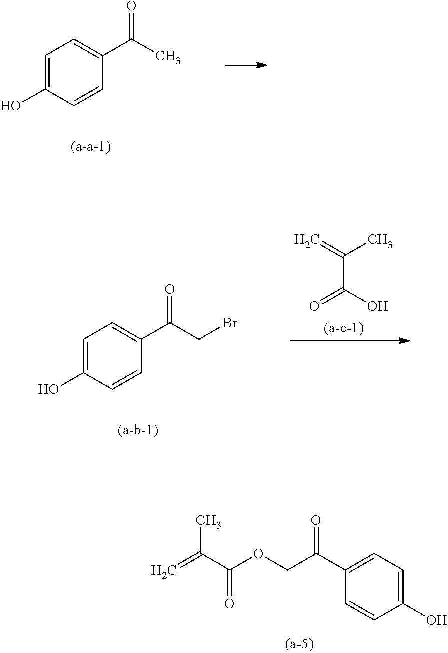

A mixture of 13.62 parts of a compound represented by the formula (a-a-1) and 23.30 parts of 1,4-dioxane was stirred at 23° C. To the mixture, a solution prepared by dissolving 25.00 parts of bromine-1,4-dioxane complex in 125 parts of 1,4-dioxane was added dropwise over 1 hour at 23° C. The resultant mixture was stirred at 23° C. for 1 hour. To the obtained mixture, 140 parts of 5% aqueous potassium carbonate solution was added, and then, 115 parts of ethyl acetate was added thereto. The resultant mixture was separated to an organic layer and an aqueous layer. The organic layer was washed with 133 parts of water followed by concentration. To the obtained residue, 50 parts of methanol was added and the resultant mixture was stirred. The recrystallization was conducted at 23° C. The precipitate was collected by filtration to obtain 17.80 parts of a compound represented by the formula (a-b-1) in the form of white solid.

A mixture of 10.00 parts of tetrahydrofuran, 1.02 parts of 1-methylpyrrolidine and 0.86 part of methacrylic acid was stirred at 23° C. To the obtained mixture, 2.15 parts of the compound represented by the formula (a-b-1) was added at 23° C., and the resultant mixture was stirred at 23° C. for 4 hours. To the obtained mixture, 10.00 parts of ion-exchanged water and 25.00 parts of ethyl acetate were added, and the resultant mixture was separated to an organic layer and an aqueous layer. The organic layer was washed with 25.00 parts of 5% aqueous potassium hydrogen carbonate solution followed by concentration. The obtained residue was purified with silica gel column chromatography (silica gel: silica gel 60-200 mesh available from Merck KGaA, eluent: heptane/ethyl acetate (volume ratio=10/1)) to obtain 0.38 part of a compound represented by the formula (a-5).

MS: 220.1

¹H-NMR (dimethylsulfoxide-d₆, Internal Standard: tetramethylsilane): δ(ppm) 1.92 (s, 3H), 5.45 (s, 2H), 5.77 (m, 1H), 6.14 (m, 1H), 6.80-6.91 (m, 2H), 7.80-7.92 (m, 2H), 10.50 (s, 1H)

### Reference Example 2

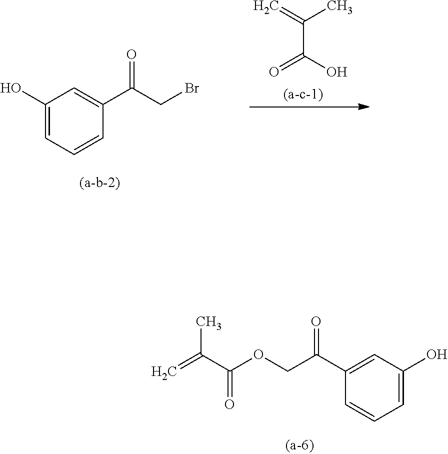

According to the same manner as that described in Reference Example 1, 0.53 part of a compound represented by the formula (a-6) was obtained except that a compound represented by the formula (a-b-2) was used in place of a compound represented by the formula (a-b-1).

MS: 220.1

¹H-NMR (dimethylsulfoxide-d₆, Internal Standard: tetramethylsilane): δ(ppm) 1.91 (s, 3H), 5.50 (s, 2H), 5.78 (m, 1H), 6.15 (m, 1H), 7.02-7.12 (m, 1H), 7.22-7.45 (m, 3H), 9.88 (bs, 1H)

### Reference Example 3

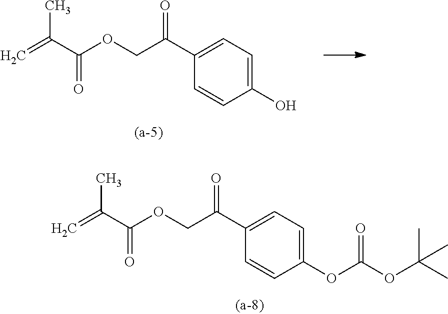

A mixture of 5.24 parts of the compound represented by the formula (a-5), 20.00 parts of tetrahydrofuran and 4.36 parts of 4-dimethylaminopyridine was stirred at 23° C. for 30 minutes. To the obtained mixture, 6.75 parts of di-tert-butyldicarbonate was added dropwise over 30 minutes, and the resultant mixture was heated up to 40° C., and then, stirred at 40° C. for 5 hours. To the obtained mixture, 1.21 parts of concentrated hydrochloric acid was added and the resultant mixture was stirred for 30 minutes. To the mixture, 40.00 parts of ethyl acetate was added, and the resultant mixture was separated to an organic layer and an aqueous layer. The organic layer was washed eight times with 10.00 parts of ion-exchanged water followed by concentration. The obtained residue was purified with silica gel column chromatography (silica gel: silica gel 60N (spherical shape, neutral, 100-210 μm available from Kanto Chemical Co., Inc., eluent: heptane/ethyl acetate (volume ratio=5/1)) to obtain 2.59 parts of a compound represented by the formula (a-8).

MS: 320.1

### Reference Example 4

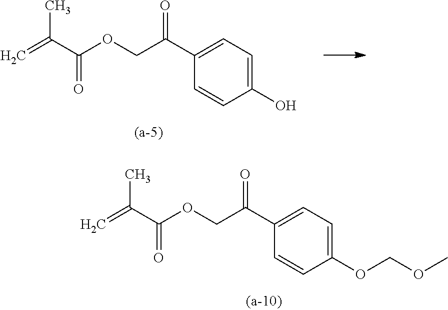

A mixture of 0.58 part of sodium hydroxide and 5.00 parts of tetrahydrofuran was stirred at 0° C. for 30 minutes. To the obtained mixture, a solution prepared by dissolving 1.46 parts of the compound represented by the formula (a-5) in 5.00 parts of tetrahydrofuran was added over 2 hours at 0° C., and then, the resultant mixture was stirred at 0° C. for 1 hour. To the obtained mixture, 0.85 part of methoxymethyl chloride was added over 40 minutes at 0° C., and then, the resultant mixture was stirred at 0° C. for 2 hours. To the obtained mixture, 10.00 parts of ion-exchanged water and 30.00 parts of ethyl acetate were added, and the resultant mixture was separated to an organic layer and an aqueous layer. The organic layer was washed eight times with 10.00 parts of ion-exchanged water followed by concentration. The obtained residue was purified with silica gel column chromatography (silica gel: silica gel 60N (spherical shape, neutral, 100-210 μm available from Kanto Chemical Co., Inc., eluent: heptane/ethyl acetate (volume ratio=5/1)) to obtain 1.13 parts of a compound represented by the formula (a-10).

MS: 264.1

### Reference Example 5

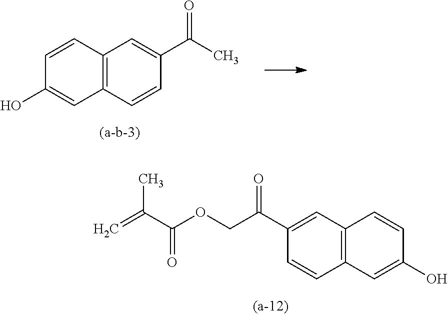

According to the same manner as that described in Reference Example 1, 0.53 part of a compound represented by the formula (a-12) was obtained except that 18.62 parts of a compound represented by the formula (a-b-3) was used in place of 13.62 parts of a compound represented by the formula (a-b-1).

MS: 270.1

### Resin Synthesis Example 1

2-Ethyl-2-adamantyl methacrylate and a compound represented by the formula (a-5) were mixed in a molar ratio of 25/75 (2-ethyl-2-adamantyl methacrylate/compound represented by the formula (a-5)), and 1,4-dioxane in 1.5 times part based on total parts of all monomers was added to prepare a mixture. To the mixture, azobisisobutyronitrile as an initiator in a ratio of 1 mol % based on all monomer molar amount and azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation, and this operation was repeated three times for purification. As a result, a resin having a weight-average molecular weight of 7.5*10³ was obtained in a yield of 74%. The resin had the following structural units. This is called as resin B1.

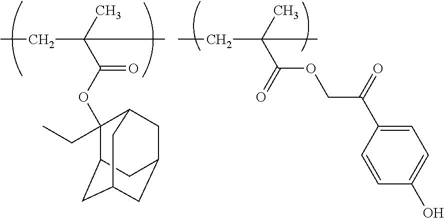

### Resin Synthesis Example 2

2-Ethyl-2-adamantyl methacrylate and a compound represented by the formula (a-6) were mixed in a molar ratio of 25/75 (2-ethyl-2-adamantyl methacrylate/compound represented by the formula (a-6)), and 1,4-dioxane in 1.5 times part based on total parts of all monomers was added to prepare a mixture. To the mixture, azobisisobutyronitrile as an initiator in a ratio of 1 mol % based on all monomer molar amount and azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation, and this operation was repeated three times for purification. As a result, a resin having a weight-average molecular weight of 8.2*10³ was obtained in a yield of 69%. The resin had the following structural units. This is called as resin B2.

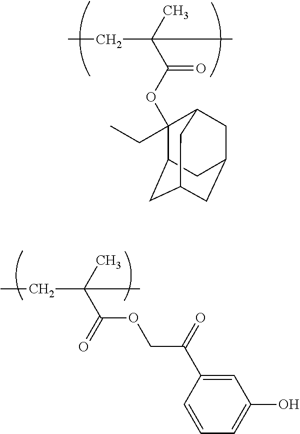

### Resin Synthesis Example 3

2-Ethyl-2-adamantyl methacrylate and a compound represented by the formula (a-8) were mixed in a molar ratio of 25/75 (2-ethyl-2-adamantyl methacrylate/compound represented by the formula (a-8)), and 1,4-dioxane in 1.5 times part based on total parts of all monomers was added to prepare a mixture. To the mixture, azobisisobutyronitrile as an initiator in a ratio of 1 mol % based on all monomer molar amount and azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation, and this operation was repeated three times for purification. As a result, a resin having a weight-average molecular weight of 6.9*10³ was obtained in a yield of 48%. The resin had the following structural units. This is called as resin B3.

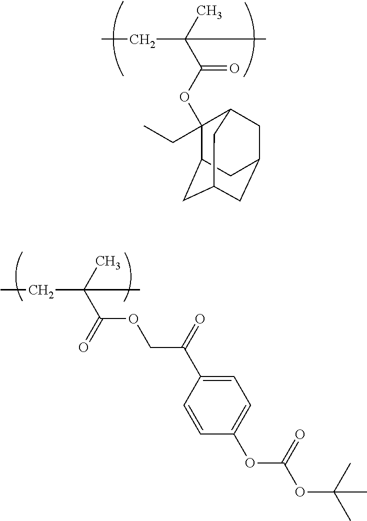

### Resin Synthesis Example 4

2-Ethyl-2-adamantyl methacrylate and a compound represented by the formula (a-10) were mixed in a molar ratio of 25/75 (2-ethyl-2-adamantyl methacrylate/compound represented by the formula (a-10)), and 1,4-dioxane in 1.5 times part based on total parts of all monomers was added to prepare a mixture. To the mixture, azobisisobutyronitrile as an initiator in a ratio of 1 mol % based on all monomer molar amount and azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation, and this operation was repeated three times for purification. As a result, a resin having a weight-average molecular weight of 6.8*10³ was obtained in a yield of 52%. The resin had the following structural units. This is called as resin B4.

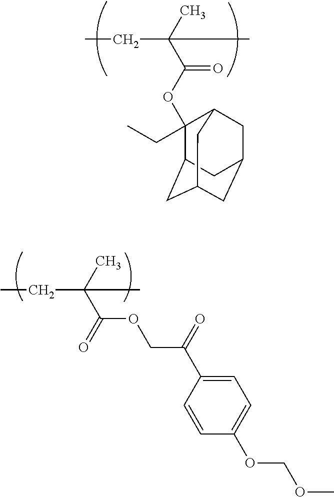

### Resin Synthesis Example 5

2-Ethyl-2-adamantyl methacrylate and a compound represented by the formula (a-12) were mixed in a molar ratio of 25/75 (2-ethyl-2-adamantyl methacrylate/compound represented by the formula (a-12)), and 1,4-dioxane in 1.5 times part based on total parts of all monomers was added to prepare a mixture. To the mixture, azobisisobutyronitrile as an initiator in a ratio of 1 mol % based on all monomer molar amount and azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation, and this operation was repeated three times for purification. As a result, a resin having a weight-average molecular weight of 7.3*10³ was obtained in a yield of 58%. The resin had the following structural units. This is called as resin B5.

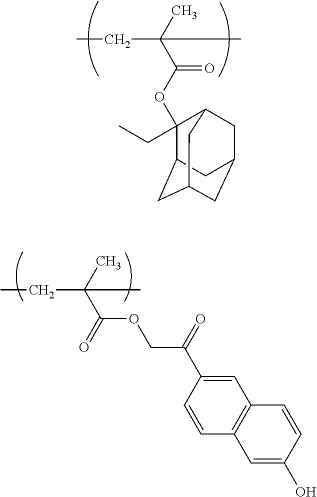

### Reference Resin Synthesis Example 1

In 265 parts of isopropanol, 39.7 parts of 2-ethyl-2-adamantyl methacrylate and 103.8 parts of p-acetoxystyrene were added to prepare a solution. The obtained solution was heated up to 75° C. under an atmosphere of nitrogen, and then, to the solution, a solution prepared by dissolving 11.05 parts of dimethyl 2,2-azobis(2-methylpropionate) in 22.11 parts of isopropanol was added dropwise. The obtained mixture was refluxed for 12 hours. The reaction mixture obtained was cooled and poured into a large amount of methanol to cause precipitation to obtain a copolymer. The obtained copolymer was filtrated to obtain 250 parts of a copolymer containing methanol. The obtained copolymer was mixed with 202 parts of methanol and 10.3 parts of 4-dimethylaminopyridine The obtained mixture was refluxed for 20 hours and then, cooled. The obtained reaction mixture was neutralized with 7.6 parts of glacial acetic acid and the resultant mixture was poured into a large amount of water to cause precipitation. The precipitate was isolated by filtration and then, dissolved in acetone. The obtained solution was poured into a large amount of water to cause precipitation. This operation was repeated three times for purification. As a result, 95.9 parts of a polymer having a weight-average molecular weight of about 8.6*10³ was obtained. The polymer had the following structural units. This is called as resin Z1. The copolymerization ratio was about 20/80 (2-ethyl-2-adamantyl methacrylate/p-hydroxystyrene). The copolymerization ratio was calculated based on the results obtained by ¹³C-NMR analysis.

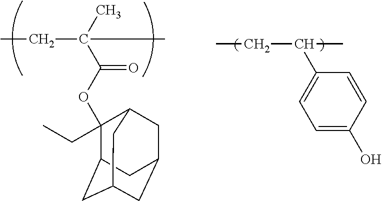

### Reference Resin Synthesis Example 2

According to the same manner as that described in Reference Resin Synthesis Example 1, 102.8 parts of a polymer having a weight-average molecular weight of about 8.2*10³ was obtained except that 59.6 parts of 2-ethyl-2-adamantyl methacrylate and 90.8 parts of p-acetoxystyrene were used in place of 39.7 parts of 2-ethyl-2-adamantyl methacrylate and 103.8 parts of p-acetoxystyrene. The polymer had the following structural units. This is called as resin Z2. The copolymerization ratio was about 30/70 (2-ethyl-2-adamantyl methacrylate/p-hydroxystyrene). The copolymerization ratio was calculated based on the results obtained by ¹³C-NMR analysis.

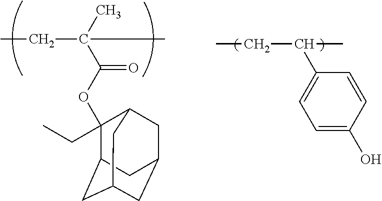

### Examples 1 to 8 and Comparative Example 1

### Acid Generator

### A1

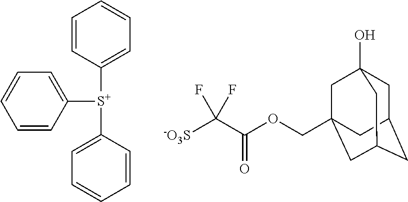

A2: triphenylsulfonium 2,4,6-triisopropylbenzenesulfonate
A3: bis(cyclohexylsulfonyl)diazomethane

### A4:

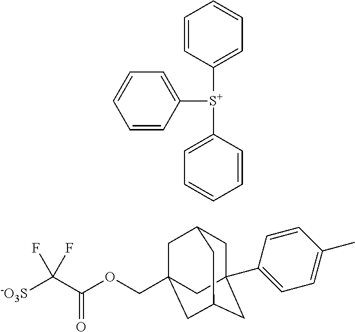

### <Resin>

### Resin B1, B2, B3, B4, B5, Z1, Z2

### <Quencher>

Q1: 2,6-diisopropylaniline
Q2: tetrabutylammonium hydroxide

### <Solvent>

| | | |
|---|---|---|
| Y1: | propylene glycol monomethyl ether acetate | 400 parts |
| | propylene glycol monomethyl ether | 100 parts |
| | γ-butyrolactone | 5 parts |

The following components were mixed and dissolved, further, filtrated through a fluorine resin filter having pore diameter of 0.2 μm, to prepare photoresist compositions.

Resin (kind and amount are described in Table 1)

Acid generator (kind and amount are described in Table 1)

Quencher (kind and amount are described in Table 1)

Solvent Y1

TABLE 1

| | Resin | Acid Generator | Quencher |
|---|---|---|---|
| | (kind/amount | (kind/amount | (kind/amount |
| Ex. No. | (part)) | (part)) | (part)) |
| Ex. 1 | B1/10 | A1/1.50 | Q1/0.03 |
| | | | Q2/0.03 |
| Ex. 2 | B2/10 | A1/1.50 | Q1/0.03 |
| | | | Q2/0.03 |
| Ex. 3 | B3/10 | A1/1.50 | Q1/0.03 |
| | | | Q2/0.03 |
| Ex. 4 | B4/10 | A1/1.50 | Q1/0.03 |
| | | | Q2/0.03 |
| Ex. 5 | B5/10 | A1/1.50 | Q1/0.03 |
| | | | Q2/0.03 |
| Ex. 6 | B1/10 | A4/1.50 | Q1/0.03 |
| | | | Q2/0.03 |
| Ex. 7 | B1/10 | A2/0.45 | Q1/0.03 |
| | | A3/0.60 | Q2/0.03 |
| Ex. 8 | B1/13.5 | A2/0.45 | Q1/0.049 |
| | | A3/0.60 | |
| Comp. Ex. 1 | Z1/6.75 | A2/0.45 | Q1/0.049 |
| | Z2/6.75 | A3/0.60 | |

Silicon wafers were each contacted with hexamethyldisilazane at 90° C. for 60 seconds on a direct hot plate and each of the resist compositions prepared as above was spin-coated over the silicon wafer to give a film thickness after drying of 0.06 μm. After application of each of the resist compositions, the silicon wafers thus coated with the respective resist compositions were each prebaked on a direct hotplate at 110° C. for 60 seconds. Using a writing electron beam lithography system (“HL-800D” manufactured by Hitachi, Ltd., 50 KeV), each wafer on which the respective resist film had been thus formed was exposed to a line and space pattern, while changing stepwise the exposure quantity.

After the exposure, each wafer was subjected to post-exposure baking on a hotplate at 110° C. for 60 seconds and then to paddle development with an aqueous solution of 2.38% by weight tetramethylammonium hydroxide for 60 seconds.

Each of a pattern developed on the silicon substrate after the development was observed with a scanning electron microscope, and the results of which are shown in Table 2.

Line Edge Roughness (LER): The photoresist pattern at the exposure dose that the line pattern and the space pattern become 1:1 after exposure through 100 nm line and space pattern mask and development was observed with a scanning electron microscope. The difference between the height of the highest point and height of the lowest point of the scabrous wall surface of the photoresist pattern was measured. When the difference is 8 nm or less, LER is good and its evaluation is marked by “◯”, and when the difference is more than 8 nm, LER is bad and its evaluation is marked by “X”. The smaller the difference is, the better the pattern is.

TABLE 2

| Ex. No. | LER |
|---|---|
| Ex. 1 | ◯ |
| Ex. 2 | ◯ |
| Ex. 3 | ◯ |
| Ex. 4 | ◯ |
| Ex. 5 | ◯ |
| Ex. 6 | ◯ |
| Ex. 7 | ◯ |
| Ex. 8 | ◯ |
| Comp. Ex. 1 | X |

Silicon wafers were each contacted with hexamethyldisilazane at 90° C. for 60 seconds on a direct hot plate and each of the resist compositions prepared as above was spin-coated over the silicon wafer to give a film thickness after drying of 0.05 μm. After application of each of the resist compositions, the silicon wafers thus coated with the respective resist compositions were each prebaked on a direct hotplate at 110° C. for 60 seconds. Using an EUV (extreme ultraviolet) exposure system, each wafer on which the respective resist film had been thus formed was exposed to a line and space pattern, while changing stepwise the exposure quantity.

After the exposure, each wafer was subjected to post-exposure baking on a hotplate at 110° C. for 60 seconds and then to paddle development with an aqueous solution of 2.38% by weight tetramethylammonium hydroxide for 60 seconds.

Each of a pattern developed on the silicon substrate after the development was observed with a scanning electron microscope, and the results of which are shown in Table 3.

Line Edge Roughness (LER): The photoresist pattern at the exposure dose that the line pattern and the space pattern become 1:1 after exposure through 50 nm line and space pattern mask and development was observed with a scanning electron microscope. The difference between the height of the highest point and height of the lowest point of the scabrous wall surface of the photoresist pattern was measured. When the difference is 7 nm or less, LER is good and its evaluation is marked by “◯”, and when the difference is more than 7 nm, LER is bad and its evaluation is marked by “X”. The smaller the difference is, the better the pattern is.

TABLE 3

| Ex. No. | LER |
|---|---|
| Ex. 1 | ◯ |
| Ex. 5 | ◯ |
| Ex. 6 | ◯ |
| Comp. Ex. 1 | X |

The present photoresist composition provides a good resist pattern having good Line edge roughness, and is especially suitable for ArF excimer laser lithography, KrF excimer laser lithography and ArF immersion lithography.

What is claimed is:

1. A photoresist composition comprising a resin which comprises a structural unit derived from a compound having an acid-labile group and a structural unit derived from a compound represented by the formula (a): 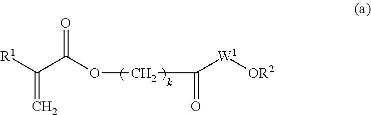
wherein R¹ represents a hydrogen atom, a halogen atom, a C1-C6 alkyl group or a C1-C6 halogenated alkyl group, k represents an integer of 1 to 6, W¹ represents a C6-C18 divalent aromatic hydrocarbon group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group, and R² represents a hydrogen atom, a group represented by the formula (R²-1) or a group represented by the formula (R²-2), 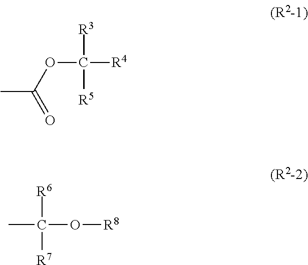
wherein R³, R⁴ and R⁵ independently each represent a C1-C12 hydrocarbon group, and R³ and R⁴ can be bonded each other to form a ring, R⁶ and R⁷ independently each represent a hydrogen atom or a C1-C12 hydrocarbon group, and R⁸ represents a C1-C12 hydrocarbon group, and
which is insoluble or poorly soluble in an alkali aqueous solution but becomes soluble in an alkali aqueous solution by the action of an acid.

2. The photoresist composition according to claim 1, wherein W¹ is a phenylene group which can have one or more substituents selected from the group consisting of a halogen atom, a hydroxyl group, a C1-C12 alkyl group, a C1-C12 alkoxy group, a C6-C14 aryl group, a C7-C15 aralkyl group, a glycidyloxy group and a C2-C4 acyl group.

3. The photoresist composition according to claim 1, wherein k is 1.

4. The photoresist composition according to claim 1, wherein the compound represented by the formula (a) is a compound represented by the formula (a-1) or (a-2): 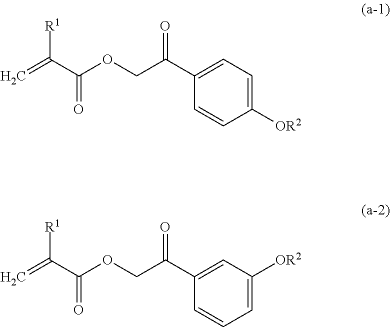
wherein R¹ and R² are the same as defined in claim 1.

5. The photoresist composition according to claim 1, wherein the photoresist composition further contains an acid generator.

6. The photoresist composition according to claim 1, wherein the photoresist composition further contains a basic compound.

7. A process for producing a photoresist pattern comprising the following steps (1) to (5):
(1) a step of applying the photoresist composition according to any one of claims 1 to 6 on a substrate,
(2) a step of forming a photoresist film by conducting drying,
(3) a step of exposing the photoresist film to radiation,
(4) a step of baking the exposed photoresist film, and
(5) a step of developing the baked photoresist film with an alkaline developer, thereby forming a photoresist pattern.
